(19) United States
(12) Patent Application Publication
(10) Pub. No.: US 2026/0006734 A1
(43) Pub. Date: Jan. 1, 2026

(54) ELECTRONIC DEVICE INCLUDING HINGE MODULE

(71) Applicant: Samsung Electronics Co., Ltd., Suwon-si (KR)

(72) Inventors: Jeong WOO, Suwon-si (KR); Sungwook CHOI, Suwon-si (KR)

(21) Appl. No.: 19/237,466

(22) Filed: Jun. 13, 2025

Related U.S. Application Data
(63) Continuation of application No. PCT/KR2025/007253, filed on May 28, 2025.

(30) Foreign Application Priority Data
Jun. 28, 2024 (KR) 10-2024-0085006
Jul. 8, 2024 (KR) 10-2024-0089809

(51) Int. Cl. H05K 5/02; H05K 5/00

(52) U.S. Cl. CPC H05K 5/0226; H05K 5/0018

(57) ABSTRACT

An electronic device may include: a first housing; a second housing; a flexible display disposed to be supported by the first housing and the second housing and configured to be bendable with respect to a folding axis; a first lower layer disposed at a position corresponding to at least a portion of the first housing under the flexible display; a second lower layer that is disposed at a position corresponding to at least a portion of the second housing under the flexible display, and arranged to have a first gap with the first lower layer in a direction parallel to the folding axis; and a hinge module including: a support body; a first rotation member rotatably coupled to the support body at one end, connected to the first housing at the other end, and at least partially supporting the first lower layer; and a second rotation member rotatably coupled to the support body at one end, connected to the second housing at the other end, and at least partially supporting the second lower layer, wherein the first rotation member may include a first recess lower than a first upper surface of the first rotation member in a region overlapping at least a first edge of the first lower layer when the flexible display is viewed from above.

### CROSS-REFERENCE TO RELATED APPLICATIONS

This application is a continuation of International Application No. PCT/KR2025/007253 designating the United States, filed on May 28, 2025, in the Korean Intellectual Property Receiving Office and claiming priority to Korean Patent Application Nos. 10-2024-0085006, filed on Jun. 28, 2024, and 10-2024-0089809, filed on Jul. 8, 2024, in the Korean Intellectual Property Office, the disclosures of each of which are incorporated by reference herein in their entireties.

### BACKGROUND

### Field

The disclosure relates to an electronic device including a hinge module.

### Description of Related Art

Electronic devices are becoming increasingly slimmer to satisfy consumers' purchasing needs as the functional gap between manufacturers is significantly reduced, and improvements are being made to increase the rigidity of electronic devices, strengthen design aspects, and differentiate their functional elements. These electronic devices are gradually changing from a uniform rectangular shape to various shapes. For example, an electronic device may have a changeable structure that is convenient to carry and enables utilization of a large-screen display when used. Electronic devices having a changeable structure may include foldable electronic devices having a bendable flexible display. Such a foldable electronic device may require an improved support structure (e.g., superior durability) to reduce breakage of the flexible display due to external impact.

The above information may be provided as background art for the purpose of assisting in understanding the disclosure. No assertion or determination is made as to whether any of the above is applicable as prior art in relation to the disclosure.

The electronic device may include a foldable electronic device that includes a first housing (e.g., first housing structure), and a second housing (e.g., second housing structure) foldably connected to the first housing via at least one hinge module (e.g., hinge structure, hinge device, or hinge assembly). The first housing and the second housing may be structurally and/or operably coupled with at least one hinge module to ensure operational reliability for the folded state and/or the unfolded state. The foldable electronic device may be operated in an in-folding manner and/or an out-folding manner by allowing the first housing to rotate in a range of 0 to 360 degrees relative to the second housing via at least one hinge module. The foldable electronic device may include a flexible display disposed to traverse the first housing and the second housing when unfolded 180 degrees.

The flexible display may be arranged to be supported by the first housing, the second housing, and at least one hinge module, and may include a folding region in which the region corresponding generally to the at least one hinge module is formed to be bendable. The foldable electronic device may include lower layers (e.g., digitizers and/or reinforcing plates) arranged to perform various functions under the flexible display. For example, the lower layers may have specific gaps to improve the bendability in the folding region of the flexible display and be arranged to correspond to the individual housings. Hence, the rear surface of the flexible display may include a step formed by the lower layers, and when an impact is applied to the stepped portion, stress may be concentrated, which may cause the flexible display to break.

To reduce the breakage of the flexible display, if the thickness of the buffering member (e.g., cushion) disposed between the flexible display and the hinge plate is increased, it may go against the slimming of the electronic device.

### SUMMARY

Embodiments of the disclosure may provide an electronic device including a hinge module having a structure capable of reducing the possibility of breakage of the flexible display due to an external impact.

Embodiments of the disclosure may provide an electronic device having a hinge module that can help improve the durability of the flexible display.

Embodiments of the disclosure may provide an electronic device including a hinge module that can aid in slimming the device.

However, the disclosure is not limited to the above, and may be expanded in various ways without departing from the spirit and scope of the disclosure.

According to various example embodiments, an electronic device may include: a first housing; a second housing; a flexible display that disposed to be supported by the first housing and the second housing and configured to be bendable with respect to a folding axis; a first lower layer disposed at a position corresponding to at least a portion of the first housing under the flexible display; a second lower layer disposed at a position corresponding to at least a portion of the second housing under the flexible display, and arranged to have a first gap with the first lower layer in a direction parallel to the folding axis; and a hinge module including: a support body; a first rotation member rotatably coupled to the support body at one end, connected to the first housing at the other end, and at least partially supporting the first lower layer; and a second rotation member rotatably coupled to the support body at one end, connected to the second housing at the other end, and at least partially supporting the second lower layer, wherein the first rotation member may include a first recess lower than a first upper surface of the first rotation member in a region overlapping at least a first edge of the first lower layer when the flexible display is viewed from above, and wherein the second rotation member may include a second recess lower than a second upper surface of the second rotation member in a region overlapping at least a second edge of the second lower layer when the flexible display is viewed from above.

The electronic device according to various example embodiments of the disclosure may include a recess that is formed to be lower than the upper surface of the rotation member so as to overlap the edge of the lower layer in the rotation member of the hinge module supporting the lower layer disposed on the rear surface of the flexible display. This recess structure may help reduce breakage and improve durability of the flexible display by dispersing stress by inducing the rear surface of the wide flexible display to make line contact with the upper surface of the rotation member rather than the edge by accommodating the edge of the lower layer in the recess due to an external impact applied to the flexible display. In addition, this recess structure may help make the electronic device slimmer by suppressing an increase in the thickness of the buffer member.

In addition, various effects may be provided that are directly or indirectly identified through this disclosure.

The effects obtainable from the disclosure are not limited to those mentioned above, and other effects not mentioned will be clearly understood by one skilled in the art to which the disclosure belongs from the description below.

### BRIEF DESCRIPTION OF THE DRAWINGS

In connection with the description of the drawings, the same or similar reference symbols may be used for identical or similar components.

FIG. 1A is a diagram illustrating a front view of an electronic device in unfolded state according to various embodiments;

FIG. 1B is a diagram illustrating a rear view of the electronic device in unfolded state according to various embodiments;

FIG. 2A is a diagram illustrating one side of the electronic device in folded state according to various embodiments;

FIG. 2B is a diagram illustrating the other side of the electronic device in folded state according to various embodiments;

FIG. 3 is an exploded perspective view of the electronic device according to various embodiments;

FIG. 4 is an exploded perspective view of a first display according to various embodiments;

FIG. 5A is a perspective view of a hinge module according to various embodiments;

FIG. 5B is a partial cross-sectional view of the hinge module in unfolded state taken along line 5-5 of FIG. 5A according to various embodiments;

FIG. 5C is a partial cross-sectional view of the hinge module in folded state taken along line 5-5 of FIG. 5A according to various embodiments;

FIG. 6A is a diagram illustrating a view of a hinge assembly according to various embodiments;

FIG. 6B is an enlarged view of region 6b in FIG. 6A according to various embodiments;

FIG. 6C is a diagram illustrating a placement structure of hinge plates and a first buffer member according to various embodiments;

FIG. 7A is a partial cross-sectional view of the electronic device taken along line 7-7 of FIG. 6B according to various embodiments;

FIG. 7B is a diagram illustrating example deformation of the flexible display due to external impact according to various embodiments;

FIG. 8A is a diagram illustrating a partial configuration of a hinge assembly according to various embodiments;

FIG. 8B is a partial cross-sectional view of the hinge assembly taken along line 8b-8b of FIG. 8A according to various embodiments;

FIG. 9A is a diagram illustrating a partial configuration of a hinge assembly according to various embodiments;

FIG. 9B is a partial cross-sectional view of the hinge assembly taken along line 9b-9b of FIG. 9A according to various embodiments;

FIG. 10A is a partial perspective view of a hinge assembly according to various embodiments;

FIG. 10B is a diagram illustrating a partial configuration of the electronic device according to various embodiments; and

FIG. 10C is a partial cross-sectional view of the electronic device taken along line 10c-10c of FIG. 10B according to various embodiments.

### DETAILED DESCRIPTION

Hereinafter, with reference to the drawings, various example embodiments of the disclosure will be described in greater detail. However, the disclosure may be implemented in various different forms and is not limited to the example embodiments described herein. In connection with the description of the drawings, the same or similar reference symbols may be used for identical or similar components. Additionally, in the drawings and related descriptions, descriptions of well-known functions and configurations may be omitted for clarity and brevity.

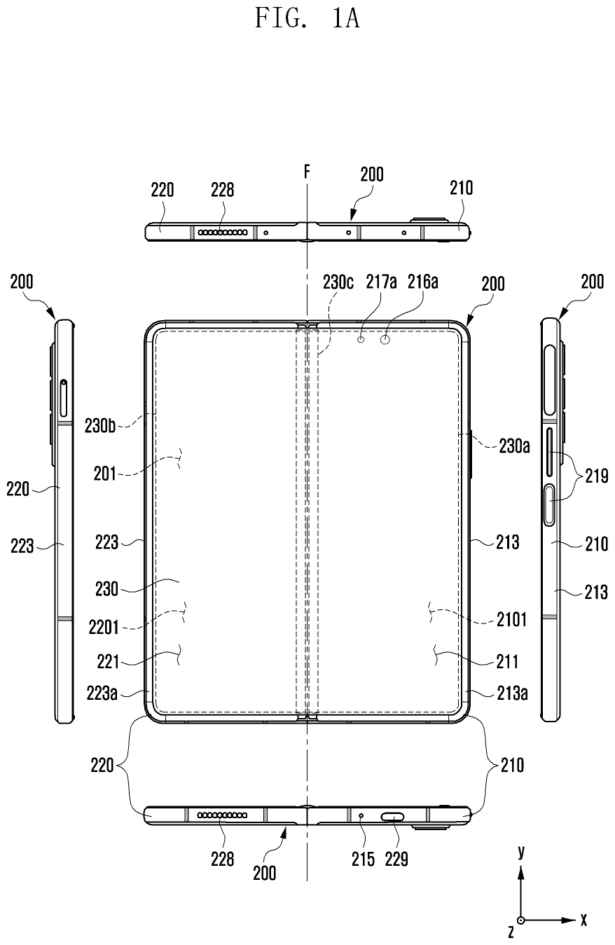

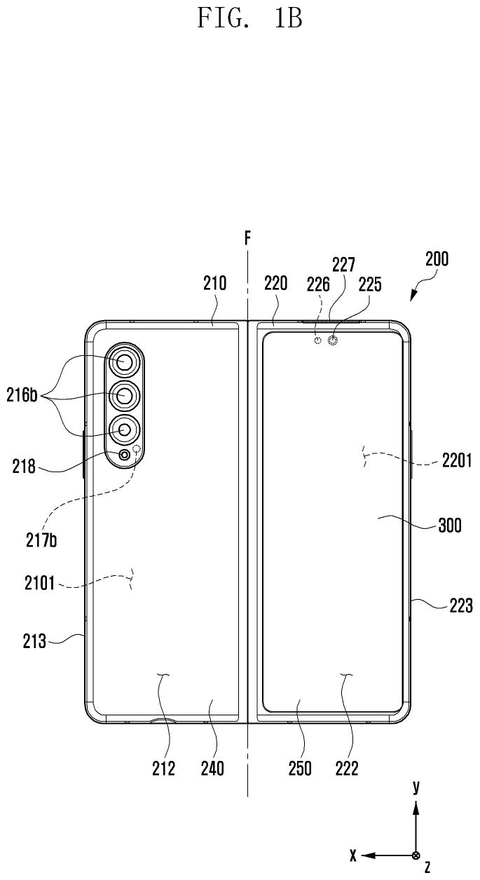

FIG. 1A is a diagram illustrating a front view of an electronic device in unfolded state according to various embodiments. FIG. 1B is a diagram illustrating a rear view of the electronic device in unfolded state according to various embodiments.

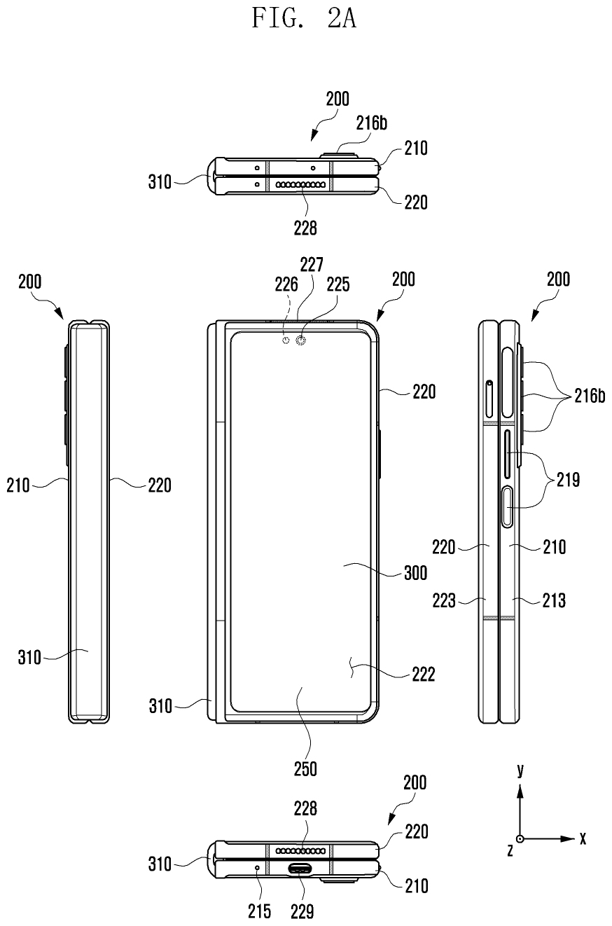

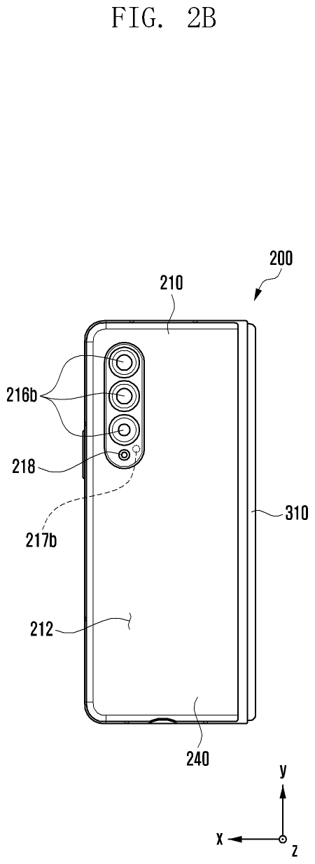

FIG. 2A is a diagram illustrating one side of the electronic device in folded state according to various embodiments. FIG. 2B is a diagram illustrating the other side of the electronic device in folded state according to various embodiments.

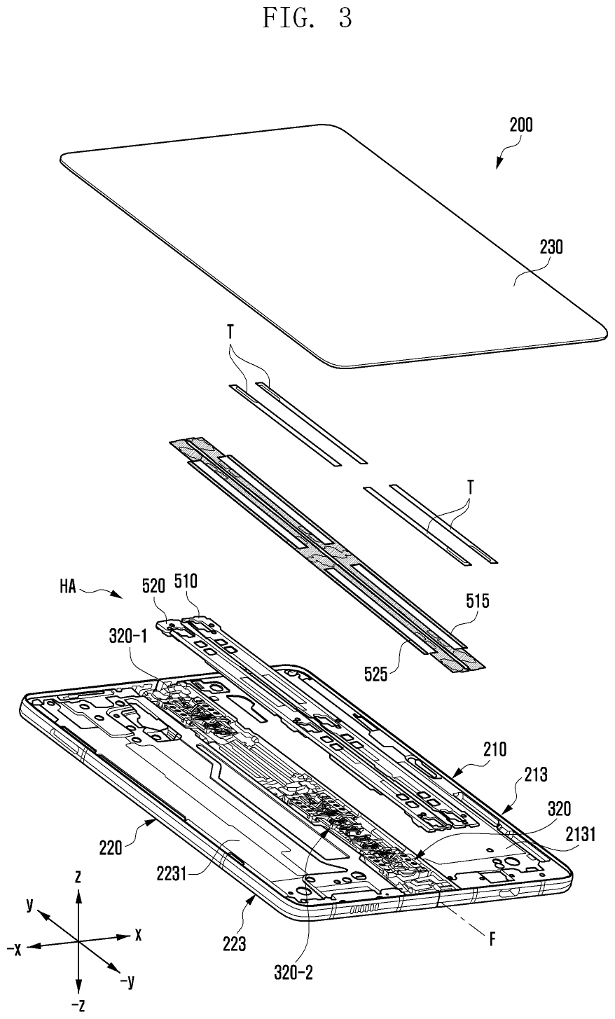

With reference to FIGS. 1A, 1B, 2A and 2B (which may be referred to as FIGS. 1A to 2B), the electronic device 200 may include a first housing 210 (e.g., first housing part or first housing structure) and a second housing 220 (e.g., second housing part or second housing structure) that are rotatably coupled to each other with respect to the folding axis (F) through at least one hinge module (e.g., hinge modules 320, 320-1 and 320-2 in FIG. 3) (e.g., hinge, hinge device, hinge structure, hinge unit, or hinge assembly). In an embodiment, the first housing 210 and the second housing 220 may be configured as the housing (e.g., foldable housing) of the electronic device 200. In an embodiment, the electronic device 200 may include a first display 230 (e.g., flexible display, foldable display, or main display) that is disposed to be accommodated or supported by the first housing and the second housing. In an embodiment, the electronic device 200 may include a second display 300 (e.g., sub-display) disposed through the second housing 220. In an embodiment, the electronic device 200 may include a hinge housing 310 (e.g., hinge cover), which is arranged so as to be at least partially invisible from the outside through the first housing 210 and the second housing 220 in the unfolded state, and cover the at least one hinge module (e.g., hinge modules 320, 320-1 and 320-2 in FIG. 3) so that it is not visible from the outside while in the folded state or while being folded. In the disclosure, the surface on which the first display 230 is disposed may be referred to as the front surface of the electronic device 200, and the opposite surface of the front surface may be referred to as the rear surface of the electronic device 200. Additionally, the surface surrounding the space between the front surface and the rear surface may be referred to as the side surface of the electronic device 200.

According to various embodiments, the first housing 210 and the second housing 220 may be arranged on both sides with respect to the folding axis (F), have a shape that is symmetrical overall with respect to the folding axis (F), and may be folded to match each other. In an embodiment, the first housing 210 and the second housing 220 may be folded asymmetrically with respect to the folding axis (F). In an embodiment, the angle or distance between the first housing 210 and the second housing 220 may be varied depending on whether the electronic device 200 is in the unfolded state, the folded state, or the intermediate state.

According to various embodiments, the first housing 210 may be rotatably connected to at least one hinge module (e.g., hinge modules 320, 320-1 and 320-2 in FIG. 3). In an embodiment, the first housing 210 may include, in the unfolded state, a first surface 211 disposed to face the front surface of the electronic device 200, a second surface 212 facing in the opposite direction of the first surface 211, and/or a first lateral member 213 surrounding at least a portion of a first space 2101 between the first surface 211 and the second surface 212.

According to various embodiments, the second housing 220 may be rotatably connected to at least one hinge module (e.g., hinge modules 320, 320-1 and 320-2 in FIG. 3). In an embodiment, the second housing 220 may include, in the unfolded state, a third surface 221 disposed to face the front surface of the electronic device 200, a fourth surface 222 facing in the opposite direction of the third surface 221, and/or a second lateral member 223 surrounding at least a portion of a second space 2201 between the third surface 221 and the fourth surface 222.

According to various embodiments, the first surface 211 may face substantially in the same direction as the third side 221 in the unfolded state, and may at least partially face the third side 221 in the folded state. In an embodiment, the electronic device 200 may include a recess 201 formed to accommodate the first display 230 through structural coupling between the first housing 210 and the second housing 220. In an embodiment, the recess 201 may have substantially the same size as the first display 230. In an embodiment, the first housing 210 may include a first protection frame 213a (e.g., first protection cover or first decorative member) that is coupled with the first lateral member 213 and is disposed to overlap the edge of the first display 230 when the first display 230 is viewed from above, thereby covering the edge of the first display 230 so that it is not visible from the outside. In an embodiment, the first protection frame 213a may be formed integrally with the first lateral member 213. In an embodiment, the second housing 220 may include a second protection frame 223a (e.g., second protection cover or first decorative member) that is coupled with the second lateral member 223 and is disposed to overlap the edge of the first display 230 when the first display 230 is viewed from above, thereby covering the edge of the first display 230 so that it is not visible from the outside. In an embodiment, the second protection frame 223a may be formed integrally with the second lateral member 223. In an embodiment, the first protection frame 213a and the second protection frame 223a may be omitted.

According to various embodiments, the hinge housing 310 (e.g., hinge cover) may be disposed between the first housing 210 and the second housing 220 so as to cover a portion of the at least one hinge module (e.g., hinge modules 320, 320-1 and 320-2 in FIG. 3). In an embodiment, the hinge housing 310 may be covered by a portion of the first housing 210 and the second housing 220 or exposed to the outside, depending on the unfolded state, the folded state, or the intermediate state of the electronic device 200. For example, when the electronic device 200 is in the unfolded state, the hinge housing 310 may be disposed to be substantially invisible from the outside due to at least a portion thereof being covered by the first housing 210 and the second housing 220. In an embodiment, when the electronic device 200 is in the folded state, the hinge housing 310 may be disposed so that at least a portion thereof is visible from the outside between the first housing 210 and the second housing 220. In an embodiment, in the intermediate state where the first housing 210 and the second housing 220 are folded with a certain angle, the hinge housing 310 may be disposed so as to be at least partially visible from the outside of the electronic device 200 between the first housing 210 and the second housing 220. For example, the area of the hinge housing 310 exposed to the outside may be less than compared with when in the fully folded state. In an embodiment, the hinge housing 310 may have an outer surface of curved, flat, or various shapes.

According to various embodiments, the electronic device 200 may include at least one of at least one display 230 and 300, input device 215 (e.g., sound input device), sound output devices 227 and 228, sensor modules 217a, 217b and 226, camera modules 216a, 216b and 225, key input device 219, indicator (not shown), or connector port 229, which is disposed in the first housing 210 and/or the second housing 220. In an embodiment, the electronic device 200 may additionally include at least one other component. In an embodiment, at least one of the components described above may be omitted.

According to various embodiments, the at least one display 230 and 300 may include a first display 230 (e.g., flexible display) that is disposed to be supported by the first surface 211 of the first housing 210 and the third surface 221 of the second housing 220, and a second display 300 that is disposed in the internal space of the second housing 220 so as to be at least partially visible from the outside through the fourth surface 222. In an embodiment, the second display 300 may be arranged in the first space 2101 of the first housing 210 so as to be visible from the outside through the second surface 212. In an embodiment, the first display 230 may be used primarily in the unfolded state of the electronic device 200, and the second display 300 may be used primarily in the folded state of the electronic device 200. In an embodiment, when in the intermediate state, the electronic device 200 may control the first display 230 and/or the second display 300 to be usable based on the folding angle between the first housing 210 and the second housing 220.

According to various embodiments, the first display 230 may be disposed in an accommodation space formed by the pair of housings 210 and 220. For example, the first display 230 may be disposed in the recess 201 formed by the pair of housings 210 and 220 so as to occupy substantially most of the front surface of the electronic device 200 in the unfolded state. In an embodiment, the first display 230 may include a flexible display whose at least a region may be changed into a flat or curved surface. In an embodiment, the first display 230 may include a first region 230a corresponding to the first housing 210 and a second region 230b corresponding to the second housing 220. In an embodiment, the first display 230 may include a folding region 230c (e.g., third region) that includes a portion of the first region 230a and a portion of the second region 230b with respect to the folding axis (F). In an embodiment, at least a portion of the folding region 230c may include a region that corresponds at least partially to the at least one hinge module (e.g., hinge modules 320, 320-1 and 320-2 in FIG. 3). In an embodiment, the regional division of the first display 230 is an illustrative demarcation made by the pair of housings 210 and 220 and the at least one hinge module (e.g., hinge modules 320, 320-1 and 320-2 in FIG. 3), and the first display 230 may display a single seamless full screen through the pair of housings 210 and 220 and the at least one hinge module (e.g., hinge modules 320, 320-1 and 320-2 in FIG. 3). In an embodiment, the first region 230a and the second region 230b may have an overall symmetrical shape or a partially asymmetrical shape with respect to the folding region 230c and/or the folding axis (F).

According to various embodiments, the electronic device 200 may include a first rear cover 240 disposed on the second surface 212 of the first housing 210, and a second rear cover 250 disposed on the fourth surface 222 of the second housing 220. In an embodiment, at least a portion of the first rear cover 240 may be formed integrally with the first lateral member 213. In an embodiment, at least a portion of the second rear cover 250 may be formed integrally with the second lateral member 223. In an embodiment, at least one of the first rear cover 240 or the second rear cover 250 may be made of a substantially transparent plate (e.g., glass plate including various coating layers, or polymer plate) or an opaque plate. In an embodiment, the first rear cover 240 may be made of an opaque plate, such as coated or colored glass, ceramic, polymer, metal (e.g., aluminum, stainless steel (STS), or magnesium), or a combination of at least two thereof. In an embodiment, the second rear cover 250 may be made of a substantially transparent plate such as glass or polymer. Hence, the second display 300 may be disposed in the second space 2201 of the second housing 220 so as to be visible from the outside through the second rear cover 250.

According to various embodiments, the input device 215 may include a microphone. In an embodiment, the input device 215 may include a plurality of microphones arranged to detect the direction of a sound. In an embodiment, the sound output devices 227 and 228 may include speakers. In an embodiment, the sound output devices 227 and 228 may include a call receiver 227 disposed through the fourth surface 222 of the second housing 220, and an external speaker 228 disposed through at least a portion of the second lateral member 223 of the second housing 220. In an embodiment, the input device 215, the sound output devices 227 and 228, and the connector 229 may be arranged in the spaces of the first housing 210 and/or the second housing 220, and may be exposed to the external environment through at least one hole formed in the first housing 210 and/or the second housing 220. In an embodiment, the holes formed in the first housing 210 and/or the second housing 220 may be used in common for the input device 215 and the sound output devices 227 and 228. In an embodiment, the sound output devices 227 and 228 may include a speaker (e.g., piezo speaker) that operates without the holes formed in the first housing 210 and/or the second housing 220.

According to various embodiments, the camera modules 216a, 216b and 225 may include a first camera module 216a disposed to photograph a subject through the first surface 211 of the first housing 210, a second camera module 216b disposed to be exposed through the second surface 212 of the first housing 210, and/or a third camera module 225 disposed to photograph a subject through the fourth surface 222 of the second housing 220. In an embodiment, the second camera module 261b may be disposed to photograph a subject through the third surface 221 of the second housing 220. In an embodiment, the electronic device 200 may include a flash 218 disposed close to the second camera module 216b. In an embodiment, the flash 218 may include, for example, a light emitting diode or a xenon lamp. In an embodiment, the camera modules 216a, 216b and 225 may include one or multiple lenses, an image sensor, and/or an image signal processor. In an embodiment, at least one of the camera modules 216a, 216b and 225 may include two or more lenses (e.g., wide-angle and telephoto lenses) and image sensors, and may be disposed together to photograph a subject through one surface of the first housing 210 and/or the second housing 220.

According to various embodiments, the sensor modules 217a, 217b and 226 may generate an electrical signal or data value corresponding to an internal operating state of the electronic device 200 or an external environmental state. In an embodiment, the sensor modules 217a, 217b and 226 may include a first sensor module 217a disposed to detect an external environment through the first surface 211 of the first housing 210, a second sensor module 217b disposed to detect an external environment through the second surface 212 of the first housing 210, and/or a third sensor module 226 disposed to detect an external environment through the fourth surface 222 of the second housing 220. In an embodiment, the sensor modules 217a, 217b and 226 may include at least one of a gesture sensor, a grip sensor, a color sensor, an infrared (IR) sensor, an illuminance sensor, an ultrasonic sensor, an iris recognition sensor, or a distance detection sensor (e.g., time of flight (TOF) sensor or light detection and ranging (LiDAR) sensor).

According to various embodiments, the electronic device 200 may further include at least one of sensor modules not shown, such as a pressure sensor, a magnetic sensor, a biometric sensor, a temperature sensor, a humidity sensor, or a fingerprint recognition sensor. In an embodiment, the fingerprint recognition sensor may be disposed through at least one lateral member among the first lateral member 213 of the first housing 210 and/or the second lateral member 223 of the second housing 220.

According to various embodiments, the key input devices 219 may be disposed to be exposed externally through the first lateral member 213 of the first housing 210. In an embodiment, the key input devices 219 may be disposed to be exposed externally through the second lateral member 223 of the second housing 220. In an embodiment, the electronic device 200 may not include some or all of the key input devices 219, and those key input devices 219 not included may be implemented in other forms, such as soft keys on at least one display 230 and 300. As an embodiment, the key input devices 219 may be implemented by utilizing a pressure sensor included in the at least one display 230 and 300.

According to various embodiments, the connector port 229 may include a connector (e.g., USB connector or interface connector port module (IF module)) for transmitting and receiving power and/or data to and from an external electronic device. In an embodiment, the connector port 229 may also perform a function for transmitting and receiving audio signals to and from the external electronic device, or may further include a separate connector port (e.g., ear jack hole) for performing a function for transmitting and receiving audio signals.

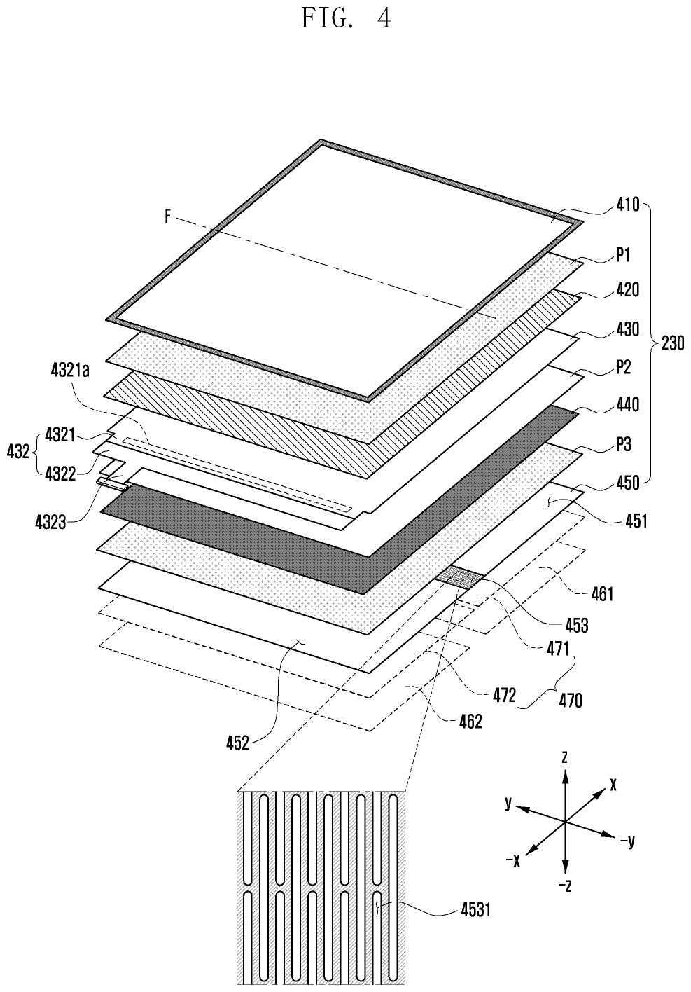

According to various embodiments, some camera modules 216a and 225, some sensor modules 217a and 226, and/or the indicator may be arranged to be visually exposed through the at least one display 230 and 300. For example, at least one camera module 216a and 225, at least one sensor module 217a and 226, and/or the indicator may be arranged below the active area (display area) of the at least one display 230 and 300 in the internal spaces of at least one housing 210 and 220 so as to come into contact with the external environment through a perforated opening or transparent region up to the cover member (e.g., window layer 410 in FIG. 4) and/or the second rear cover 250. In an embodiment, the area where at least one display 230 and 300 and at least one camera module 216a and 225 face may be formed as a transmissive region having a specific transmittance as part of the area displaying the content. In an embodiment, the transmissive region may be formed to have a transmittance in the range of about 5 percent to about 20 percent. This transmissive region may include a region overlapping with the effective area (e.g., field of view area) of at least one camera module 216a and 225 through which light passes to form an image through image formation of the image sensor. For example, the transmissive region of the at least one display 230 and 300 may include a region with a lower pixel density compared to the surrounding regions. For example, the transmissive region may replace the opening. For example, the at least one camera module 216a and 225 may include an under display camera (UDC) or an under panel camera (UPC). As an embodiment, some of the camera modules 216a and 225 or sensor modules 217a and 226 may be arranged so as to perform their functions without being visually exposed through the display. For example, the region facing the camera modules 216a and 225 and/or sensor modules 217a and 226 disposed under the displays 230 and 300 (e.g., display panel) may have an under display camera (UDC) structure, so that a perforated opening may be not necessary.

According to various embodiments, when the electronic device 200 is in the unfolded state (e.g., the state of FIG. 1A and FIG. 1B), the first housing 210 and the second housing 220 may make an angle of about 180 degrees, and the first region 230a, the second region 230b, and the folding region 230c of the first display 230 may be disposed to be on substantially the same plane and face in the same direction (e.g., z-axis direction). As an embodiment, when the electronic device 200 is in the unfolded state, the first housing 210 may be rotated at an angle of about 360 degrees with respect to the second housing 220 so that the second surface 212 and the fourth surface 222 face each other, folding in the opposite direction (out folding scheme).

According to various embodiments, when the electronic device 200 is in the folded state (e.g., the state of FIGS. 2A and 2B), the first surface 211 of the first housing 210 and the third surface 221 of the second housing 220 may be disposed to face each other. In this case, the first region 230a and the second region 230b of the first display 230 may be arranged to face each other through the folding region 230c while forming a narrow angle (e.g., in the range of 0 degrees to about 10 degrees). In an embodiment, at least a portion of the folding region 230c may be changed to a curved shape having a specific curvature. In an embodiment, when the electronic device 200 is in the intermediate state, the first housing 210 and the second housing 220 may be disposed to make a specific angle with respect to each other. In this case, the first region 230a and the second region 230b of the first display 230 may make an angle that is greater than that for the folded state and less than that for the unfolded state, and the curvature of the folding region 230c may be less than that for the folded state and greater than that for the unfolded state. In an embodiment, the first housing 210 and the second housing 220 may make an angle at which they can stop at a designated folding angle between the folded state and the unfolded state through at least one hinge module (e.g., hinge modules 320, 320-1 and 320-2 in FIG. 3) (free stop functionality). In an embodiment, the first housing 210 and the second housing 220 may be pressurized to maintain a state (free stop) or to continuously operate in the unfolding or folding direction with respect to a specified inflection angle through at least one hinge module (e.g., hinge modules 320, 320-1 and 320-2 in FIG. 3).

FIG. 3 is an exploded perspective view of the electronic device according to various embodiments.

With reference to FIG. 3, the electronic device 200 may include a first housing 210, a second housing 220, at least one hinge module 320, 320-1 and 320-2 that rotatably connects the first housing 210 and the second housing 220 with respect to each other, and a flexible display 230 (e.g., first display 230 in FIG. 1A) that is supported by or at least partially accommodated in the first housing 210 and the second housing 220. In an embodiment, the first housing 210 may include a first lateral member 213 that is exposed to be visible from the outside of the electronic device 200 and includes at least a portion of the side surface, and a first extension member 2131 that is extended from the first lateral member 213 into the internal space (e.g., first space 2101 in FIG. 1A) of the first housing 210. In an embodiment, the second housing 220 may include a second lateral member 223 that is exposed to be visible from the outside of the electronic device 200 and includes at least a portion of the side surface, and a second extension member 2231 that is extended from the second lateral member 223 into the internal space (e.g., second space 2201 in FIG. 1A) of the second housing 220. In an embodiment, the flexible display 230 may be disposed to be supported by at least a portion of the first extension member 2131 and the second extension member 2231.

According to various embodiments, the at least one hinge module 320, 320-1 and 320-2 may rotatably connect the first housing 210 and the second housing 220 along the folding axis (F) direction (e.g., +y-axis direction), and may include a first hinge module 320 disposed generally at one end (e.g., bottom) of the electronic device 200, a second hinge module 320-1 disposed generally at the other end (e.g., bottom) of the electronic device 200, and a third hinge module 320-2 disposed between the first hinge module 320 and the second hinge module 320-1. In an embodiment, the electronic device 200 may include one hinge module, two hinge modules disposed at a specified interval, or four or more hinge modules disposed at specified intervals. In an embodiment, the hinge modules 320, 320-1 and 320-2 may each have substantially the same configuration.

According to various embodiments, the electronic device 200 may include a first hinge plate 510 disposed under the flexible display 230 on one side of the folding axis (F) in correspondence to at least a portion of the first housing 210, and a second hinge plate 520 disposed under the flexible display 230 on the other side of the folding axis (F) in correspondence to at least a portion of the second housing 220. In an embodiment, the first hinge plate 510 may be coupled with at least one hinge module 320, 320-1 and 320-2. In an embodiment, the second hinge plate 520 may be coupled with at least one hinge module 320, 320-1 and 320-2. In an embodiment, the first hinge plate 510 and the second hinge plate 520 may be made of a metal material. In an embodiment, the first hinge plate 510 and the second hinge plate 520 may be made at least partially of a non-metallic material to reduce the weight of the electronic device 200. In an embodiment, the first hinge plate 510 and the second hinge plate 520 may be made of carbon fiber reinforced plastic (CFRP) or polycarbonate (PC) having the strength for supporting the flexible display 230. In an embodiment, the at least one hinge module 320, 320-1 and 320-2 and the first and second hinge plates 510 and 520 coupled thereto may be configured as a hinge assembly (HA).

According to various embodiments, the electronic device 200 may include first buffer members 515 and 525 disposed between the first hinge plate 510 and the flexible display 230 and/or between the second hinge plate 520 and the flexible display 230. In an embodiment, the first buffer members 515 and 525 may be made of an elastic material (e.g., foam, rubber, or urethane) having a specified thickness to buffer an external impact (e.g., ball drop) applied in the direction of the hinge assembly (HA) (e.g., negative z-axis direction) from the upper surface of the flexible display 230. In an embodiment, at least portions of the first buffer members 515 and 525 may be replaced with a tape member (T) (e.g., adhesive member) to reinforce adhesion between the flexible display 230 and the hinge plates 510 and 520.

FIG. 4 is an exploded perspective view of the first display according to various embodiments. In the following description, the first display may be referred to as “flexible display”.

The flexible display (e.g., first display 230 in FIG. 1A) according to various example embodiments of the disclosure may include an unbreakable (UB) type OLED display (e.g., curved display). However, without being limited thereto, the flexible display 230 may include a flat type display based on the OCTA (on cell touch AMOLED (active matrix organic light-emitting diode)) technology.

With reference to FIG. 4, the flexible display 230 (e.g., first display in FIG. 1A) may include a window layer 410, a polarizing layer (POL (polarizer)) 420 (e.g., polarizing film), a display panel 430, a polymer layer 440, and a support plate 450, which are sequentially arranged on the rear surface of the window layer 410 (e.g., in negative z-axis direction). In an embodiment, the polymer layer 440 and/or the support plate 450 may be omitted. In an embodiment, the electronic device (e.g., electronic device 200 in FIG. 1A) may include lower layers disposed under the flexible display 230. In an embodiment, the lower layers may be disposed in a manner of being attached to the rear surface of the flexible display 230. In an embodiment, the lower layers may include a first lower layer disposed at a position corresponding to at least a portion of the first housing 210 below the support plate 450, and a second lower layer disposed at a position corresponding to at least a portion of the second housing 220. In an embodiment, the first lower layer may include a first reinforcing plate 461 and/or a first digitizer 471 that are at least partially disposed under the support plate 450. In an embodiment, if the first reinforcing plate 461 and the first digitizer 471 are arranged together, the first digitizer 471 may be disposed between the support plate 450 and the first reinforcing plate 461. In an embodiment, the second lower layer may include a second reinforcing plate 462 and/or a second digitizer 472 that are at least partially disposed under the support plate 450. In an embodiment, if the second reinforcing plate 462 and the second digitizer 472 are arranged together, the second digitizer 472 may be disposed between the support plate 450 and the second reinforcing plate 462. In an embodiment, the first digitizer 471 and the second digitizer 472 may be integrally formed and disposed as a single digitizer 470, in which case the region corresponding to the folding region (e.g., folding region 230c in FIG. 1A) of the flexible display 230 may be formed to be bendable. In an embodiment, the digitizer 470 may be disposed between the polymer layer 440 and the support plate 450. For example, if the flexible display 230 is a POL-less display, the polarizing layer may be omitted, and a transparent reinforcing layer (e.g., buffer layer) may be further disposed at the corresponding position. In an embodiment, the reinforcing plates 461 and 462 and/or the digitizer 470 may be omitted.

According to various embodiments, the window layer 410 may include a glass layer. In an embodiment, the window layer 410 may include ultra thin glass (UTG). In an embodiment, the window layer 410 may include a polymer. In this case, the window layer 410 may include PET (polyethylene terephthalate) or PI (polyimide). In an embodiment, the window layer 410 may be arranged in multiple layers including a glass layer and a polymer. In an embodiment, the flexible display 230 may further include a coating layer formed on at least a portion of the upper surface, the rear surface, or the side surface of the glass layer formed as part of the window layer 410 or the polymer (e.g., protection film layer) disposed on top of the glass layer. In such a case, the coating layer may include a hard coating layer (HC layer), an anti-reflection/low reflection (AR/LR) coating layer, a shatter proof (SP) coating layer, and/or an anti-fingerprint (AF) coating layer. In an embodiment, the coating layer may be formed on at least one of the side surface of the polymer, the rear surface or the side surface of the glass layer between the polymer and the glass layer.

According to various embodiments, the window layer 410, the polarizing layer 420, the display panel 430, the polymer layer 440, and the support plate 450 may be arranged to traverse at least a portion of the first surface (e.g., first surface 211 in FIG. 1A) of the first housing (e.g., first housing 210 in FIG. 1A) and the third surface (e.g., third surface 221 in FIG. 1A) of the second housing (e.g., second housing 220 in FIG. 1A). In an embodiment, the window layer 410, the polarizing layer 420, the display panel 430, the polymer layer 440, the support plate 450, and the digitizers 471 and 472 may be attached to each other via adhesives P1, P2 and P3 (or, glue). For example, the adhesives P1, P2 and P3 may include at least one of an optical clear adhesive (OCA), a pressure sensitive adhesive (PSA), a heat-reactive adhesive, a regular adhesive, or a double-sided tape. In an embodiment, the reinforcing plates 461 and 462 that can be replaced or added instead of the digitizers may provide rigidity for the flexible display 230 and may be used as a ground to prevent or reduce malfunction of the flexible display 230. In an embodiment, the reinforcing plates 461 and 462 may be made of a metal material. In an embodiment, the reinforcing plates 461 and 462 may be made of SUS or Al.

According to various embodiments, the display panel 430 may include a plurality of pixels and wiring structures (e.g., electrode pattern). In an embodiment, the polarizing layer 420 may selectively transmit light that is generated from a light source of the display panel 430 and vibrates in a specific direction. In an embodiment, the display panel 430 and the polarizing layer 420 may be formed integrally. In an embodiment, the flexible display 230 may include a touch panel (not shown).

According to various embodiments, the polymer layer 440 may be disposed under the display panel 430 to provide a dark background for securing visibility of the display panel 430, and may be made of a buffer material for buffering. In an embodiment, to waterproof the flexible display 230, the polymer layer 440 may be removed or disposed under the support plate 450. In an embodiment, the polymer layer 440 may be omitted if the support plate is made of an opaque material.

According to various embodiments, the support plate 450 may provide region-specific rigidity and bending characteristics for the flexible display 230. For example, the support plate 450 may be made of a non-metallic thin-plate material having rigid properties for supporting the display panel 430, such as fiber reinforced plastics (FRP) (e.g., carbon fiber reinforced plastics (CFRP) or glass fiber reinforced plastics (GFRP)). In an embodiment, the support plate 450 may include a first flat portion 451 corresponding to the first housing (e.g., first housing 210 in FIG. 1A), a second flat portion 452 corresponding to the second housing (e.g., second housing 220 in FIG. 1A), and a flexible portion 453 (or, bending portion) connecting the first flat portion 451 and the second flat portion 452. In an embodiment, the flexible portion 453 may be formed to have a pattern 4531 for improving the bendability. In an embodiment, the pattern 4531 may include a plurality of openings formed to penetrate from the upper surface to the rear surface of the support plate at specified intervals and/or a plurality of recesses formed lower than the outer surface without penetrating. In an embodiment, the bending characteristics of the flexible portion 453 may be determined by at least one of the size, shape, or arrangement density of at least some openings among the plurality of openings of the pattern 4531. In an embodiment, the support plate 450 may be formed of a metallic material such as SUS (steel use stainless) (e.g., STS (stainless steel)), Cu, Al, or metal CLAD (e.g., laminated member in which SUS and Al are alternately arranged). In such a case, a plurality of openings may be formed throughout the entire area of the support plate 450 so as to induce a detection operation of the digitizer 470 disposed below. In an embodiment, the support plate 450 may be used to help reinforce the rigidity of the electronic device (e.g., electronic device 200 of FIG. 1A), shield ambient noise, and dissipate heat emitted from surrounding heat-emitting components.

According to various embodiments, the flexible display 230 may include at least one functional member (not shown) disposed between the polymer layer 440 and the support plate 450 or under the support plate 450. In an embodiment, the functional member may include a graphite sheet for heat dissipation, a force-touch FPCB, a fingerprint sensor FPCB, an antenna radiator for communication, or a conductive/non-conductive tape. In an embodiment, if the functional member is not bendable, it may be individually disposed in the first housing (e.g., first housing 210 in FIG. 1A) and the second housing (e.g., second housing 220 in FIG. 1A). In an embodiment, if the functional member is bendable, it may be disposed from the first housing (e.g., first housing 210 in FIG. 1A) through the at least one hinge module (e.g., hinge modules 320, 320-1 and 320-2 in FIG. 3) to at least a portion of the second housing (e.g., second housing 220 in FIG. 1A).

According to various embodiments, the flexible display 230 may include a bending part 432 disposed in a manner of being folded from the display panel 430 to at least a portion of the rear surface of the flexible display 230 (e.g., in negative z-axis direction). In an embodiment, the bending part 432 may include an extension portion 4321 that is extended from the display panel 430 and includes a control circuit 4321a, and a flexible board 4322 (e.g., flexible printed circuit board (FPCB)) that is electrically connected to the extension portion 4321 and includes a plurality of electrical components. In an embodiment, the control circuit 4321a may include a DDI (display driver IC) or TDDI (touch display driver IC) disposed on the extension portion 4321 having an electrical wiring structure. In an embodiment, the bending part 432 may include a COP (chip on panel or chip on plastic) structure in which the control circuit 4321a is directly disposed on the extension portion 4321. In an embodiment, the bending part 432 may include a COF (chip on film) structure in which the control circuit 4321a is disposed on a separate connection film (not shown) connecting the extension portion 4321 and the flexible board 4322. In an embodiment, the flexible display 230 may include a plurality of electrical components (not shown) arranged on the flexible board 4322. In an embodiment, the flexible display 230 may include a connector portion 4323 that is extended from the flexible board 4322 and is electrically connected to a board (e.g., main printed circuit board) disposed in the internal space of the electronic device 200. In an embodiment, the plurality of electrical components may include at least one of touch IC, flash memory for the display, ESD protection diode, pressure sensor, or fingerprint sensor.

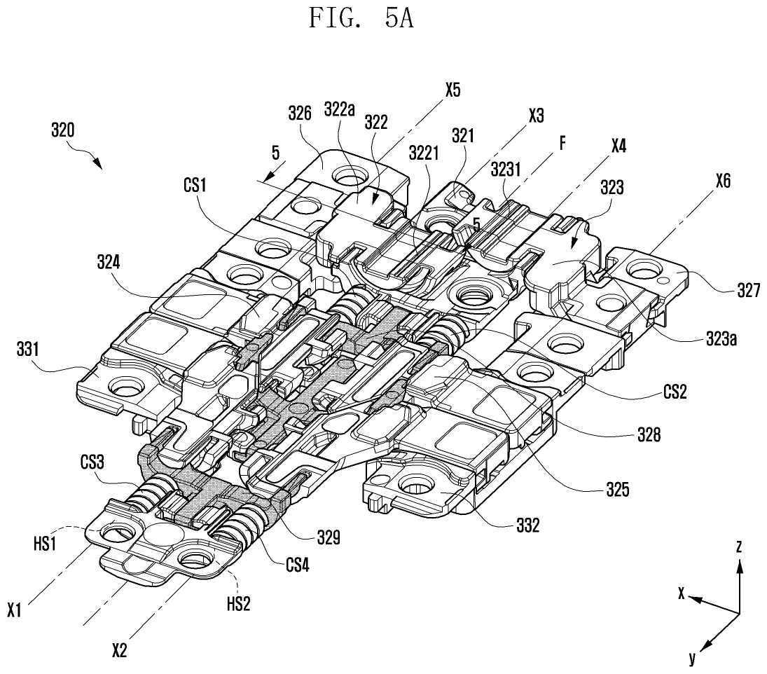

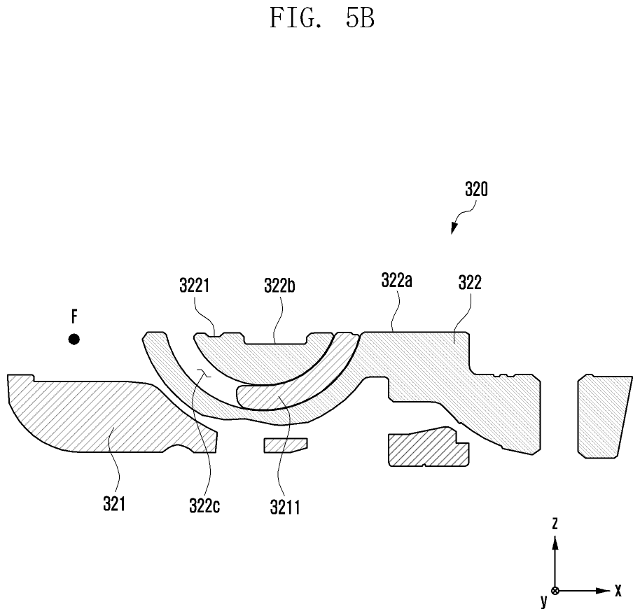

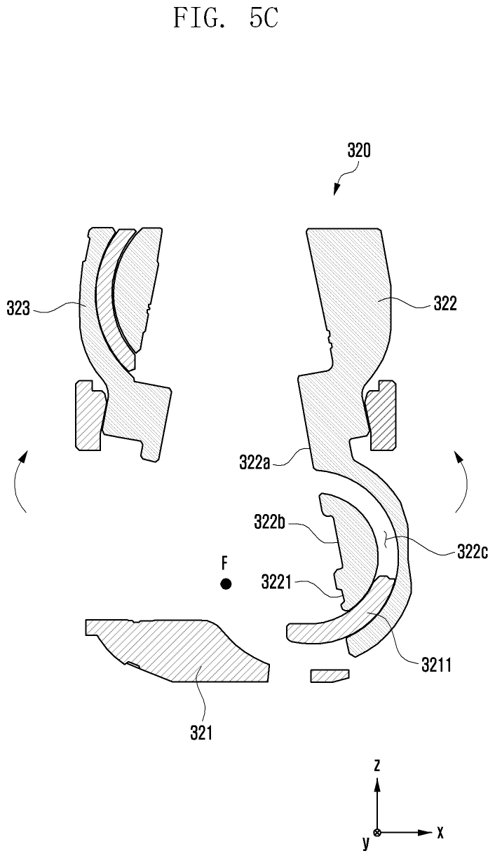

FIG. 5A is a perspective view of the hinge module according to various embodiments. FIG. 5B is a partial cross-sectional view of the hinge module in unfolded state taken along line 5-5 of FIG. 5A according to various embodiments. FIG. 5C is a partial cross-sectional view of the hinge module in folded state taken along line 5-5 of FIG. 5A according to various embodiments.

With reference to FIGS. 5A, 5B and 5C (which may be referred to as FIGS. 5A to 5C), the hinge module 320 (e.g., first hinge module 320, second hinge module 320-1, and/or third hinge module 320-2 in FIG. 3) may include a support body 321 (e.g., rotator bracket, support bracket, or bracket) fixed to the hinge housing (e.g., hinge housing 310 in FIG. 2A) through a fastening member such as a screw, a first shaft HS1 rotatably coupled to the support body 321 with respect to a first rotation axis (X1), a second shaft HS2 rotatably coupled to the support body 321 with respect to a second rotation axis (X2) spaced apart from the first rotation axis (X1), a first rotation member 322 (e.g., first rotator) rotatably coupled to the support body 321 with respect to a third rotation axis (X3), a second rotation member 323 (e.g., second rotator) rotatably coupled to the support body 321 with respect to a fourth rotation axis (X4), a first fixing body 326 rotatably coupled to the first rotation member 322 with respect to a fifth rotation axis (X5), a second fixing body 327 rotatably coupled to the second rotation member 323 with respect to a sixth rotation axis (X6), a first arm member 324 (e.g., first hinge arm) whose one end is rotatably coupled to the first shaft HS1 with respect to the first rotation axis (X1), and a second arm member 325 (e.g., second hinge arm) whose one end is rotatably coupled to the second shaft HS2 with respect to the second rotation axis (X2). In an embodiment, the first fixing body 326 may be fixed to the first housing (e.g., first housing 210 in FIG. 3). In an embodiment, the second fixing body 327 may be fixed to the second housing (e.g., second housing 220 in FIG. 3). In an embodiment, the hinge module 320 may include a first link 331 that is fixed to the first housing (e.g., first housing 210 in FIG. 3) and guides the other end of the first arm member 324 to move, and a second link 332 that is fixed to the second housing (e.g., second housing 220 in FIG. 3) and guides the other end of the second arm member 325 to move. In an embodiment, the first link 331 may be fixed to the first housing (e.g., first housing 210 in FIG. 3), and the second link 332 may be fixed to the second housing (e.g., second housing 220 in FIG. 3). In an embodiment, the first link 331 may be formed integrally with the first fixing body 326. In an embodiment, the second link 332 may be formed integrally with the second fixing body 327.

According to various embodiments, the hinge module 320 may include a first cam structure 328 cam-coupled with a cam structure formed at one end of the arm members 324 and 325, and a second cam structure 329 cam-coupled with a cam structure formed at the other end of the arm members 324 and 325. In an embodiment, the hinge module 320 may include a first torque generating structure that generates torque by applying pressure to the first cam structure 328 in the direction of the arm members 324 and 325 (e.g., in y-axis direction) through a first elastic member CS1 (e.g., first spring) arranged in a manner of penetrating the first shaft HS1 and a second elastic member CS2 (e.g., second spring) arranged in a manner of penetrating the second shaft HS2.

According to various embodiments, the hinge module 320 may include a second torque generating structure that generates torque by applying pressure to the second cam structure 329 in the direction of the arm members 324 and 325 (e.g., y-axis direction) through a third elastic member CS3 (e.g., third spring) arranged in a manner of penetrating the first shaft HS1 and a fourth elastic member CS4 (e.g., fourth spring) arranged in a manner of penetrating the second shaft HS2. In an embodiment, through the first torque generating structure and the second torque generating structure, the hinge module 320 may provide a pressing force in the rotation direction to transition the first housing (e.g., first housing 210 in FIG. 3) and the second housing (e.g., second housing 220 in FIG. 3) from the unfolded state to the folded state or from the folded state to the unfolded state, or provide a free-stop function to stop the first housing (e.g., first housing 210 in FIG. 3) and the second housing (e.g., second housing 220 in FIG. 3) in an intermediate state between the folded state and the unfolded state.

According to various embodiments, the first rotation member 322 may be coupled to the support body 321 in such a manner that the curved guide rib 3211 formed on the support body 321 is rotatably guided along the curved guide slit 322c formed at the corresponding position of the first rotation member 322. In an embodiment, the second rotation member 323 may also be coupled to the support body 321 in substantially the same manner. In an embodiment, the first fixing body 326 and the second fixing body 327 may also be coupled respectively to the first rotation member 322 and the second rotation member 323 in a similar manner. In an embodiment, the first arm member 324 and the second arm member 325 may also be coupled respectively to the first link 331 and the second link 332 in a similar manner.

According to various embodiments, the electronic device (e.g., electronic device 200 in FIG. 3) may include, between the hinge module 320 and the flexible display (e.g., flexible display 230 in FIG. 3), a first hinge plate (e.g., first hinge plate 510 in FIG. 3) disposed to have a length along the direction of the folding axis (F), and a second hinge plate (e.g., second hinge plate 520 in FIG. 3) disposed to be spaced apart from the first hinge plate 510. In an embodiment, at least a portion of the first hinge plate 510 and at least a portion of the second hinge plate 520 may be arranged to support the lower layers (e.g., first digitizer 471 and second digitizer 472 in FIG. 4) disposed on the rear surface of the flexible display 230. In an embodiment, at least a portion of the hinge module 320 may be exposed from the hinge plates 510 and 520 and disposed to directly support the lower layers 471 and 472. For example, at least a portion of the first rotation member 322 and the second rotation member 323 may be arranged parallel to the hinge plates 510 and 520, for example, in the x-axis direction and/or the y-axis direction without having a stacked structure (e.g., placed on the same plane as the hinge plates 510 and 520 to support the lower layers 471 and 472), thereby helping to reduce the overall thickness of the electronic device 200.

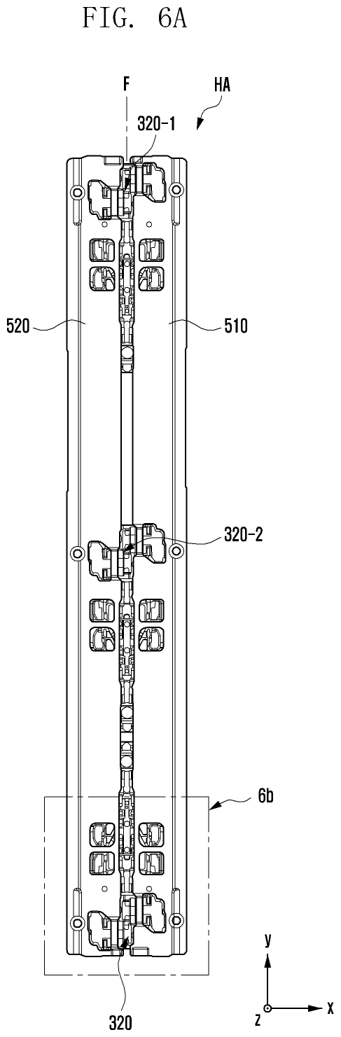

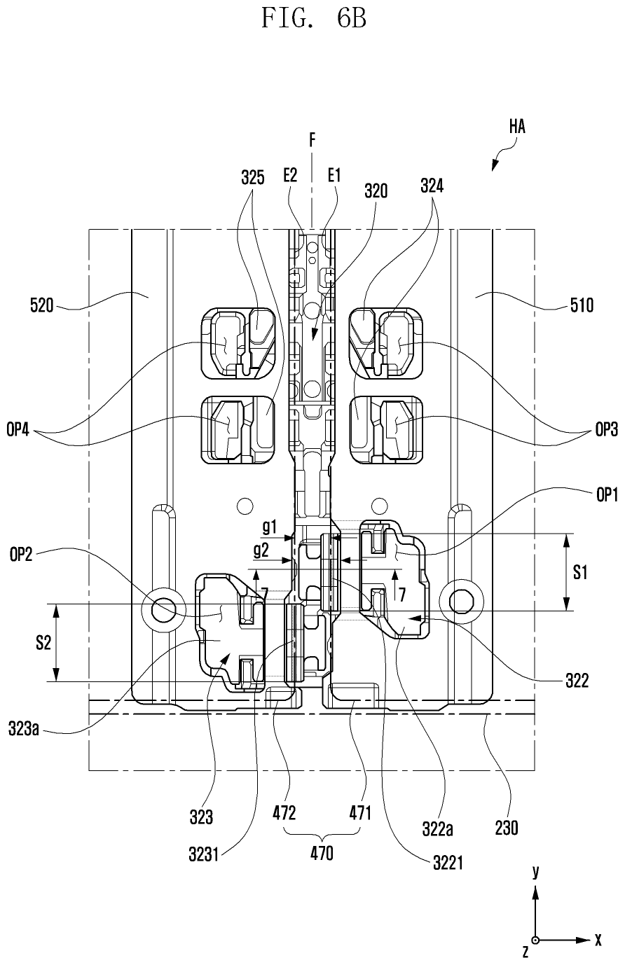

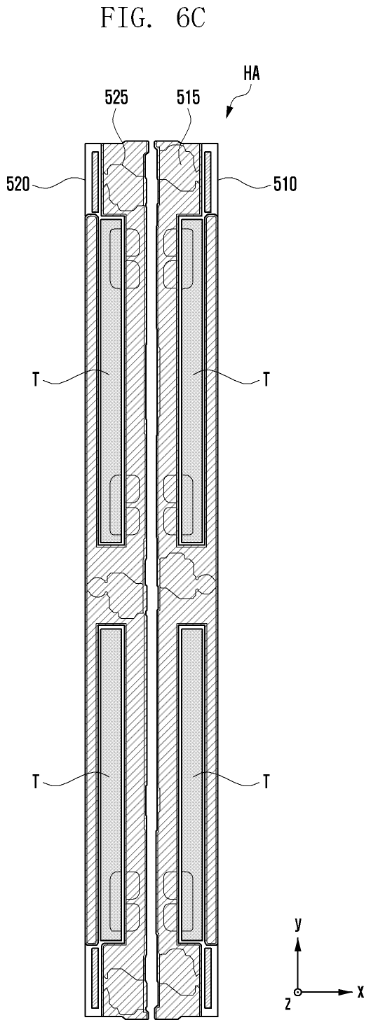

According to various embodiments, the first upper surface 322a of the first rotation member 322 may be disposed to support at least a portion of the first lower layer 471 including a first edge (e.g., first edge E1 in FIG. 6B). In this case, when an external impact is applied to the flexible display 230, stress is concentrated around the first edge E1 due to the step difference between the rear surface of the flexible display 230 and the first lower layer 471, which may increase the possibility of damage to the flexible display 230.

According to an example embodiment of the disclosure, the first rotation member 322 may include a first recess 3221 formed lower than the first upper surface 322a in a region overlapping at least the first edge E1 of the first lower layer 471 when the flexible display 230 is viewed from above. In an embodiment, when the flexible display 230 is deformed by an external impact, the first recess 3221 may reduce the possibility of damage to the flexible display 230 by inducing the first edge E1 to be received in the first recess 3221 and the rear surface of the flexible display 230 to come into line contact with the upper surface 322a of the first rotation member 322. This is because the stress that may be concentrated around the stepped first edge E1 is dispersed around the rear surface of the flexible display 230 that is in relatively wide contact with the upper surface of the first rotation member through the first recess 3221 that accommodates the first edge E1. In an embodiment, the second rotation member 323 may also include a second recess 3231 formed lower than the second upper surface 323a in a region overlapping at least the second edge (e.g., second edge E2 in FIG. 6B) of the second lower layer 472 when the flexible display 230 is viewed from above, thereby providing substantially the same effect (e.g., stress dissipation effect).

FIG. 6A is a diagram illustrating a view of a hinge assembly according to various embodiments. FIG. 6B is an enlarged view of region 6b in FIG. 6A according to various embodiments.

With reference to FIGS. 6A and 6B, the hinge assembly HA may include one or more hinge modules 320, 320-1 and 320-2 arranged at specific intervals along the folding axis (F) direction (e.g., y-axis direction). In an embodiment, the hinge assembly HA may include a first hinge plate 510 disposed to be supported by the at least one hinge module 320, 320-1 and 320-2, and a second hinge plate 520 disposed to be spaced apart from the first hinge plate 510.

According to various embodiments, the first hinge plate 510 may be disposed to support a portion of the first lower layer 471 disposed at a position largely corresponding to the first housing (e.g., first housing 210 in FIG. 3) on the rear surface of the flexible display 230. According to an embodiment, the second hinge plate 520 may be disposed to support a portion of the second lower layer 472 that is arranged (e.g., attached) on the rear surface of the flexible display 230 and is disposed at a position largely corresponding to the second housing (e.g., second housing 220 in FIG. 3). In an embodiment, the first lower layer 471 and the second lower layer 472 may be arranged to have a first gap (g1) in a direction perpendicular to the folding axis (F) (e.g., x-axis direction).

According to various embodiments, the first hinge plate 510 and the second hinge plate 520 may be arranged to have a second gap (g2) in a direction perpendicular to the folding axis (F) (e.g., x-axis direction). In an embodiment, when the flexible display 230 is viewed from above, at least a portion of the first rotation member 322 and at least a portion of the second rotation member 323 among the components of the hinge module 320 may be exposed through the second gap (g2) while not overlapping respectively with the first hinge plate 510 and the second hinge plate 520. Hence, the exposed portion of the first rotation member 322 and the exposed portion of the second rotation member 323 can be placed on the same plane as the first hinge plate 510 and the second hinge plate 520, thereby enabling the rear surface of the first lower layer 471 and the second lower layer 472 to be supported evenly.

According to various embodiments, the first lower layer 471 may be arranged such that, when the flexible display 230 is viewed from above, the first edge E1 positioned in a direction parallel to the folding axis (F) (e.g., y-axis direction) overlaps with a portion of the first rotation member 322 exposed through the second gap (g2). In an embodiment, the second lower layer 472 may be arranged such that, when the flexible display 230 is viewed from above, the second edge E2 positioned in a direction parallel to at least the folding axis (F) (e.g., y-axis direction) overlaps with a portion of the second rotation member 323 exposed through the second gap (g2). In an embodiment, the first gap (g1) between the first edge E1 of the first lower layer 471 and the second edge E2 of the second lower layer 472 may be not the same for each region along the length direction (e.g., y-axis direction). In an embodiment, the second gap (g2) between the first hinge plate 510 and the second hinge plate 520 may be not the same for each region along the length direction (e.g., y-axis direction). In an embodiment, in a first section S1 where at least a portion of the first rotation member 322 is exposed through the second gap (g2), the first gap (g1) may be set to be equal to or smaller than the second gap (g2). In an embodiment, in a second section S2 where at least a portion of the second rotation member 323 is exposed through the second gap (g2), the first gap (g1) may be set to be equal to or smaller than the second gap (g2).

According to various embodiments, the first rotation member 322 may include a first recess 3221 formed to be lower than the first upper surface 322a in a region overlapping with at least the first edge E1 when the flexible display 230 is viewed from above. In an embodiment, a portion of the first recess 3221 may be disposed at a position overlapping the first gap (g1) when the flexible display 230 is viewed from above. In an embodiment, the remaining portion of the first recess 3221 may be disposed at a position not overlapping the first gap (g1) when the flexible display 230 is viewed from above. In an embodiment, the first recess 3221 may be disposed at a position overlapping the second gap (g2) when the flexible display 230 is viewed from above. In an embodiment, the first recess 3221 may be formed in the first section S1. In an embodiment, the first recess 3221 may be formed to have a depth equal to or greater than the step provided by the rear surface of the flexible display 230 and the first edge E1 of the first lower layer 471. For example, the first recess 3221 may be formed at a depth such that, when the flexible display 230 is deformed by an external impact, the rear surface of the flexible display 230 makes line contact with the first upper surface 322a of the first rotation member 322 before the first edge E1 of the first lower layer 471 comes into contact with the surface (e.g., bottom surface) of the first recess 3221.

According to various embodiments, the second rotation member 323 may include a second recess 3231 formed to be lower than the second upper surface 323a in a region overlapping at least the second edge E2 when the flexible display 230 is viewed from above. In an embodiment, a portion of the second recess 3231 may be disposed at a position overlapping the first gap (g1) when the flexible display 230 is viewed from above. In an embodiment, the remaining portion of the second recess 3231 may be disposed at a position not overlapping the first gap (g1) when the flexible display 230 is viewed from above. In an embodiment, the second recess 3231 may be disposed at a position overlapping the second gap (g2) when the flexible display 230 is viewed from above. In an embodiment, the second recess 3231 may be formed in the second section S2. In an embodiment, the second recess 3231 may be formed to have a depth equal to or greater than the step provided by the second edge E2 of the second lower layer 472 and the rear surface of the flexible display 230. For example, the second recess 3231 may be formed at a depth such that, when the flexible display 230 is deformed by an external impact, the rear surface of the flexible display 230 makes line contact with the second upper surface 323a of the second rotation member 323 before the second edge E2 of the second lower layer 472 comes into contact with the surface (e.g., the bottom surface) of the second recess 3231.

According to various embodiments, the hinge assembly HA provides a space between the first hinge plate 510 and the second hinge plate 520, and the hinge housing (e.g., hinge housing 310 in FIG. 2A) in a region not corresponding to the at least one hinge module 320, 320-1 and 320-2, so that an external impact applied to the flexible display 230 can be absorbed or dispersed through the elasticity of the first and second hinge plates 510 and 520 that are moveable in the space.

According to various embodiments, the first hinge plate 510 may include a first opening OP1 arranged largely in the first section S1. In an embodiment, the first rotation member 322 may be arranged to directly support the rear surface of the first lower layer 471 or the rear surface of the flexible display 230 by exposing at least a portion of the first upper surface 322a adjacent to the first recess 3221 through the first opening OP1. For example, the portion of the first rotation member 322 exposed through the first opening OP1 and the surface of the first hinge plate 510 are placed on the same plane, which can induce easy support of the flexible display 230, and can at least partially avoid the stacked structure of the first hinge plate 510 and the first rotation member 322, which can help achieve slimming of the electronic device (e.g., electronic device 200 of FIG. 3). In addition, the portion of the first upper surface 322a exposed through the first opening OP1 and the second gap (g2) may induce extension of the guide slit (e.g., guide slit 322c in FIG. 5B), which increases the amount of engagement between the guide rib (e.g., guide rib 3211 in FIG. 5B) and the support body (e.g., support body 321 in FIG. 5B), providing improved operational reliability.

According to various embodiments, the second hinge plate 520 may include a second opening OP2 arranged largely in the second section S2. In an embodiment, the second rotation member 323 may be disposed to directly support the rear surface of the second lower layer 472 or the rear surface of the flexible display by exposing at least a portion of the second upper surface 323a adjacent to the second recess 3231 through the second opening OP2. For example, the portion of the second rotation member 323 exposed through the second opening OP2 and the surface of the second hinge plate 520 may be placed on the same plane, inducing easy support of the flexible display 230.

According to various embodiments, the first hinge plate 510 may further include at least one third opening OP3 to directly apply pressure to the first lower layer 471 or the rear surface of the flexible display 230 by exposing at least a portion of the first arm member 324 of the hinge module 320. In an embodiment, the second hinge plate 520 may further include at least one fourth opening OP4 to directly apply pressure to the second lower layer 472 or the rear surface of the flexible display 230 by exposing at least a portion of the second arm member 325 of the hinge module 320. For example, the portion of the first arm member 324 exposed through the third opening OP3 and the surface of the first hinge plate 510 may be placed on the same plane, thereby inducing easy support of the flexible display 230. In an embodiment, the portion of the second arm member 325 exposed through the fourth opening OP4 and the surface of the second hinge plate 520 may be placed on the same plane, thereby inducing easy support of the flexible display 230. In an embodiment, the exposure structure in which the first arm member 324 is exposed through the third opening OP3 of the first hinge plate 510 and the exposure structure in which the second arm member 325 is exposed through the fourth opening OP4 of the second hinge plate 520 may contribute to avoiding overlapping arrangement among the hinge plates 510 and 520 and the arm members 324 and 325, helping achieve sliming of the electronic device 200.

FIG. 6C is a diagram illustrating a placement structure of hinge plates and a first buffer member according to various embodiments.

With reference to FIG. 6C, the hinge assembly HA may include first buffer members 515 and 525 (e.g., first cushion) disposed between the first hinge plate 510 and the first lower layer 471 and between the second hinge plate 520 and the second lower layer 472. In an embodiment, the first buffer members 515 and 525 may be used to buffer and/or disperse the external impact applied to the flexible display 230. In an embodiment, at least portions of the first buffer members 515 and 525 may be replaced with or added by a tape member (T) (e.g., double-sided tape) to enhance the adhesion between the first and second hinge plates 510 and 520 and the first and second lower layers 471 and 472. In an embodiment, the first buffer members 515 and 525 may be formed to have sizes that do not overlap with the first recess 3221 and the second recess 3231 at least in the first section S1 and the second section S2 when the flexible display 230 is viewed from above. In an embodiment, the first buffer members 515 and 525 may be positioned to substantially overlap the first lower layer 471 and the second lower layer 472 in sections other than the first section S1 and the second section S2 when the flexible display 230 is viewed from above.

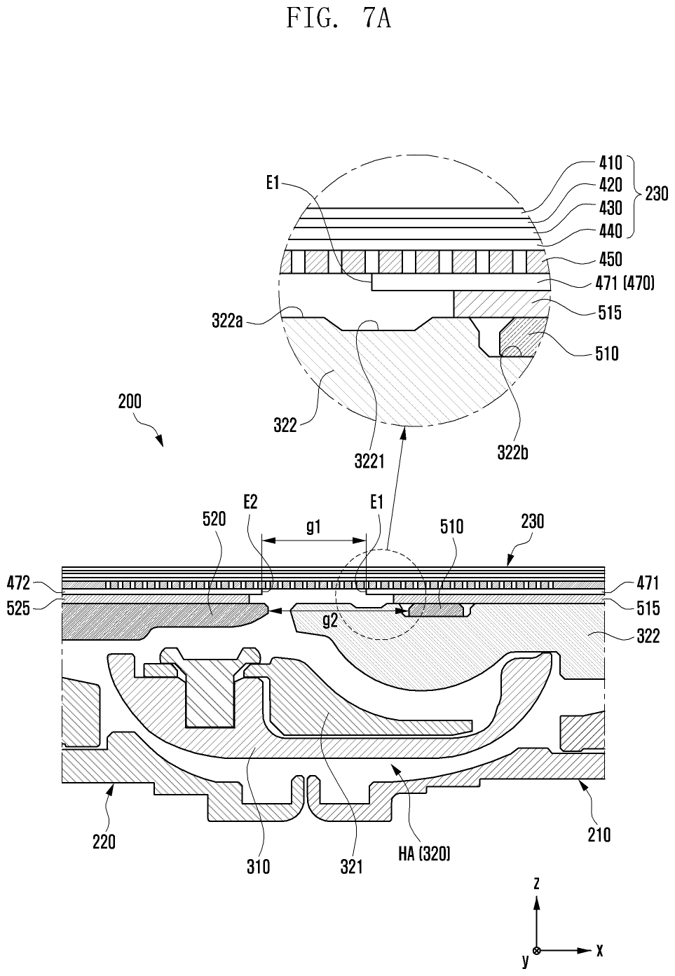

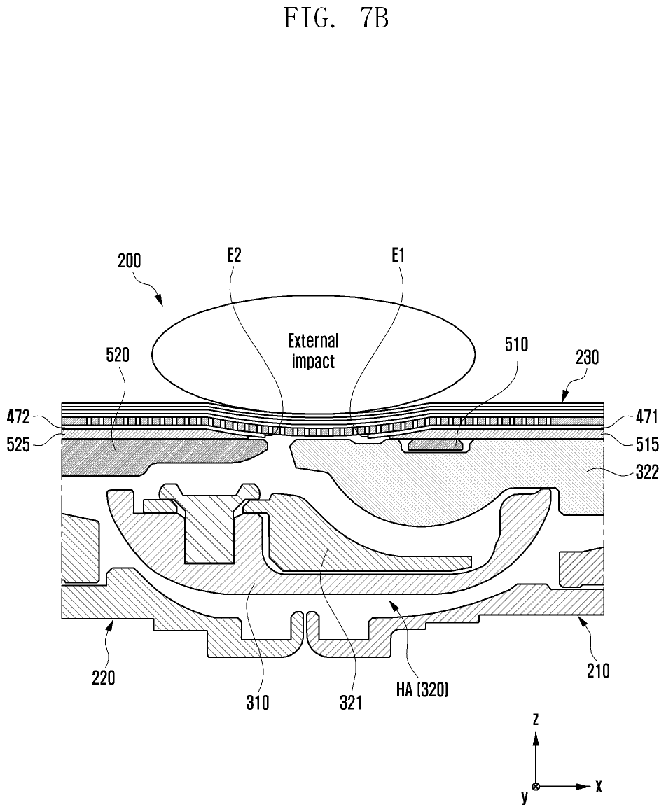

FIG. 7A is a partial cross-sectional view of the electronic device taken along line 7-7 of FIG. 6B according to various embodiments. FIG. 7B is a diagram illustrating example deformation of the flexible display due to external impact according to various embodiments.

With reference to FIGS. 7A and 7B, the electronic device 200 may include a first housing 210, a second housing 220, a hinge assembly HA that rotatably connects the first housing 210 and the second housing 220, and a flexible display 230 disposed to be supported by the first housing 210, the second housing 220, and the hinge assembly HA. In an embodiment, the flexible display 230 may include a window layer 410, a polarizing layer 420, a display panel 430, a polymer layer 440, and a support plate 450, which are sequentially arranged under the window layer 410. In an embodiment, the electronic device 200 may include a first lower layer 471 disposed under the support plate 450 and largely corresponding to the first housing 210, and a second lower layer 472 disposed under the support plate 450 and largely corresponding to the second housing 220. In an embodiment, the first lower layer 471 and the second lower layer 472 may be disposed in a manner that they are attached to the rear surface of the support plate 450 to be spaced apart from each other with a first gap (g1). In an embodiment, the first lower layer 471 and the second lower layer 472 may include a first digitizer 471 and a second digitizer 472 that are spaced apart from each other, as a digitizer 470. In an embodiment, the first lower layer 471 and the second lower layer 472 may include reinforcing plates (e.g., reinforcing plates 461 and 462 in FIG. 4).

According to various embodiments, the hinge assembly HA may include a hinge housing 310, a hinge module 320 fixed to the hinge housing, a first hinge plate 510 disposed at least partially between the hinge module 320 and the first lower layer 471 on top of the hinge module 320, and a second hinge plate 520 disposed at least partially between the hinge module 320 and the second lower layer 472. In an embodiment, the electronic device 200 may include first buffer members 515 and 525 disposed between the first hinge plate 510 and the first lower layer 471 and between the second hinge plate 520 and the second lower layer 472. In an embodiment, at least a portion of the first lower layer 471 and at least a portion of the second lower layer 472 may be disposed to be supported respectively by the first hinge plate 510 and the second hinge plate 520. For example, when the electronic device 200 transitions to the unfolded state through the hinge module 320, the first hinge plate 510 may be formed to support the flexible display 230 in a manner that it comes into contact with at least a portion of the first lower layer 471, and the second hinge plate 520 may be formed to support the flexible display 230 in a manner that it comes into contact with at least a portion of the second lower layer 472. In an embodiment, when the electronic device 200 transitions to the folded state through the hinge module 320, at least a portion of the flexible display 230 may be formed to be supported in a manner that at least a portion of the first hinge plate 510 becomes spaced apart from the first lower layer 471 and at least a portion of the second hinge plate 520 becomes spaced apart from the second lower layer 472.

According to various embodiments, in the first section S1 where at least a portion of the first rotation member 322 is exposed through the second gap (g2), the first gap (g1) may be set to be equal to or smaller than the second gap (g2). In an embodiment, in the second section S2 where at least a portion of the second rotation member 323 is exposed through the second gap (g2), the first gap (g1) may be set to be equal to or smaller than the second gap (g2).

According to various embodiments, the first rotation member 322 may include a first recess 3221 formed to be lower than the first upper surface 322a of the first rotation member 322 in a region overlapping with at least the first edge E1 of the first lower layer 471 when the flexible display 230 is viewed from above. In an embodiment, the first recess 3221 may be disposed at a position where a portion thereof overlaps the first gap (g1) and the remaining portion thereof does not overlap the first gap (g1) when the flexible display 230 is viewed from above. In an embodiment, the first recess 3221 may be disposed at a position overlapping the second gap (g2) when the flexible display 230 is viewed from above. In an embodiment, the first recess 3221 may be formed to have a depth equal to or greater than the step provided through the rear surface of the flexible display 230 and the first edge E1 of the first lower layer 471. In an embodiment, the step may be provided by a height difference formed from the rear surface of the flexible display 230 to the first lower layer 471 and the first buffer member 515. For example, the first recess 3221 may be formed to have a depth such that, when the flexible display 230 is deformed by an external impact, before the first edge E1 of the first lower layer 471 comes into contact with the surface (e.g., bottom surface) of the first recess 3221, the rear surface of the flexible display 230 (e.g., rear surface of the flexible display corresponding to the first gap) makes line contact with the first upper surface 322a of the first rotation member 322. Hence, when the flexible display 230 is deformed by an external impact, the first recess 3221 may reduce the possibility of damage to the flexible display 230 by allowing the first edge E1 to be accommodated in the first recess 3221 and the relatively wide rear surface of the flexible display 230 to make line contact with the upper surface 322a of the first rotation member 322.

According to various embodiments, the first rotation member 322 may include a receiving groove 322b formed to be lower than the first upper surface 322a in at least a portion of the first section (e.g., first section S1 in FIG. 6B) where the first recess 3221 is disposed. In an embodiment, the receiving groove 322b may be formed to have a depth that can accommodate a portion of the first hinge plate 510. In an embodiment, the depth of the receiving groove 322b may be formed such that the portion of the first hinge plate 510 received in the first receiving groove 322b does not protrude beyond the first upper surface 322a, or coincides with the first upper surface 322a. Through the receiving structure in which at least a portion of the first hinge plate 510 is received in the receiving groove 322b of the first rotation member 322, the stacked structure of the first hinge plate 510 and the first rotation member 510 is avoided at least in the first section S1, which can help reduce the thickness of the electronic device 200. In an embodiment, the second rotation member (second rotation member 323 in FIG. 6B) may also include a receiving groove, which can accommodate at least a portion of the second hinge plate 520 in substantially the same manner, arranged in the second section (e.g., second section S2 in FIG. 6B) where the second recess (e.g., second recess 3231 in FIG. 6B) is disposed.

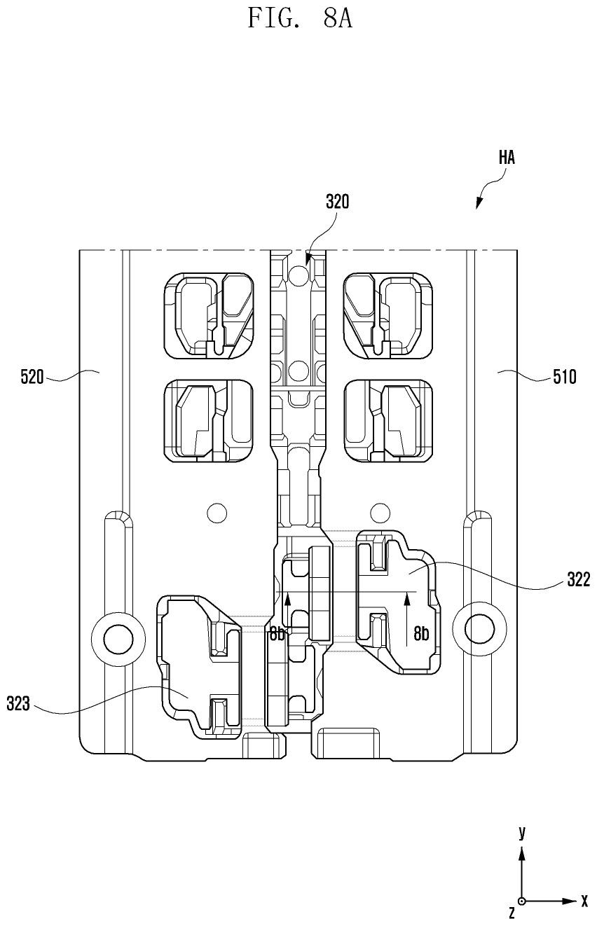

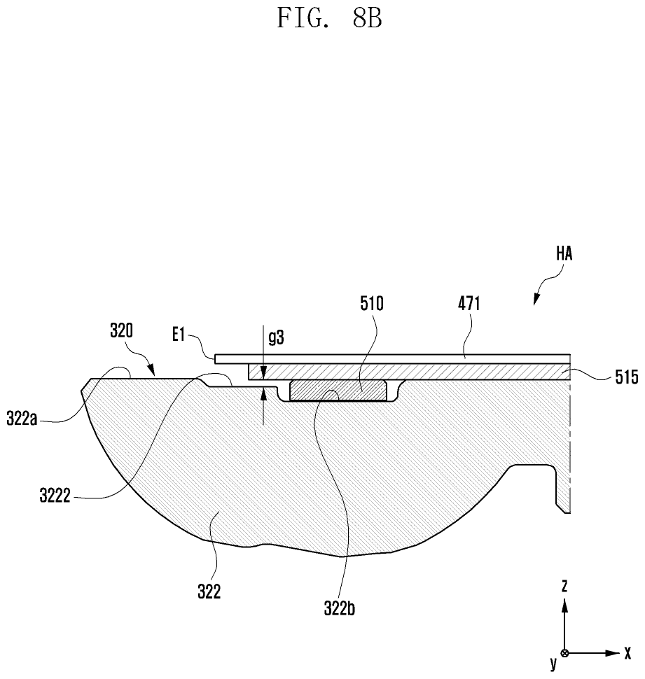

FIG. 8A is a diagram illustrating a partial configuration of the hinge assembly according to various embodiments. FIG. 8B is a partial cross-sectional view of the hinge assembly taken along line 8b-8b of FIG. 8A according to various embodiments.

In describing the hinge assembly HA of FIGS. 8A and 8B, components that are substantially the same as those of the hinge assembly HA of FIG. 7A are given the same reference symbols, and detailed descriptions thereof may be omitted.

With reference to FIGS. 8A and 8B, the hinge assembly HA may include a hinge module 320, a first hinge plate 510 disposed at least partially between the hinge module 320 and the first lower layer 471, and a second hinge plate 520 disposed at least partially between the hinge module 320 and the second lower layer 472, which are on top of the hinge module 320. In an embodiment, the electronic device 200 may include a first buffer member 515 disposed between the first hinge plate 510 and the first lower layer 471. In an embodiment, at least a portion of the first lower layer 471 may be disposed to be supported by the first hinge plate 510.

According to various embodiments, the first rotation member 322 may include a first recess 3222 formed to be lower than the first upper surface 322a of the first rotation member 322 in a region overlapping at least the first edge E1 of the first lower layer 471 when the flexible display 230 is viewed from above. In an embodiment, the first recess 3222 may be formed in a manner of extending up to the first receiving groove 322b. In this case, a relatively wide gap (g3) may be secured between the first buffer member 515 and the first recess 3222, which may be advantageous for effective dispersion of external impact. In an embodiment, the recess formed in the second rotation member 323 may also be formed in substantially the same manner as the first recess 3222.

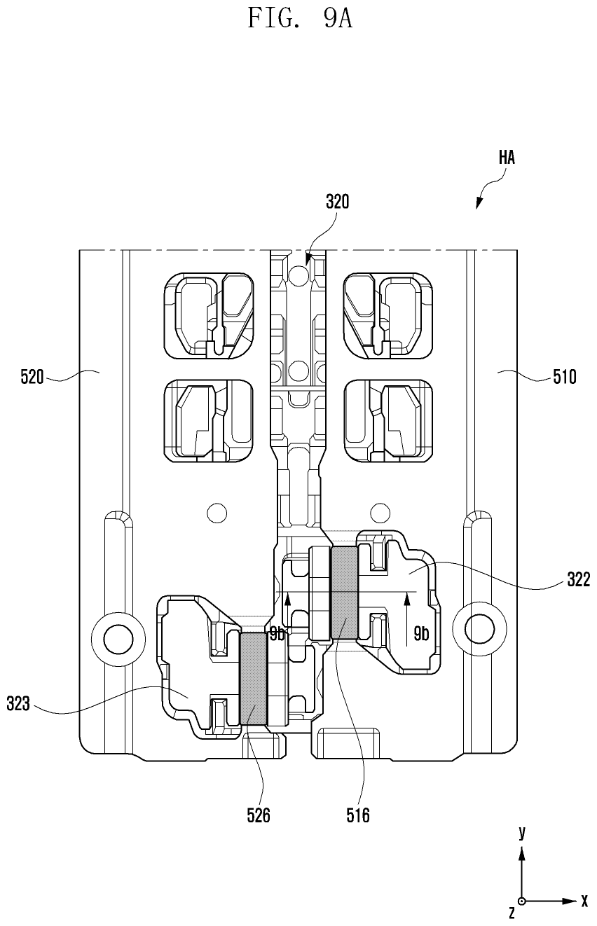

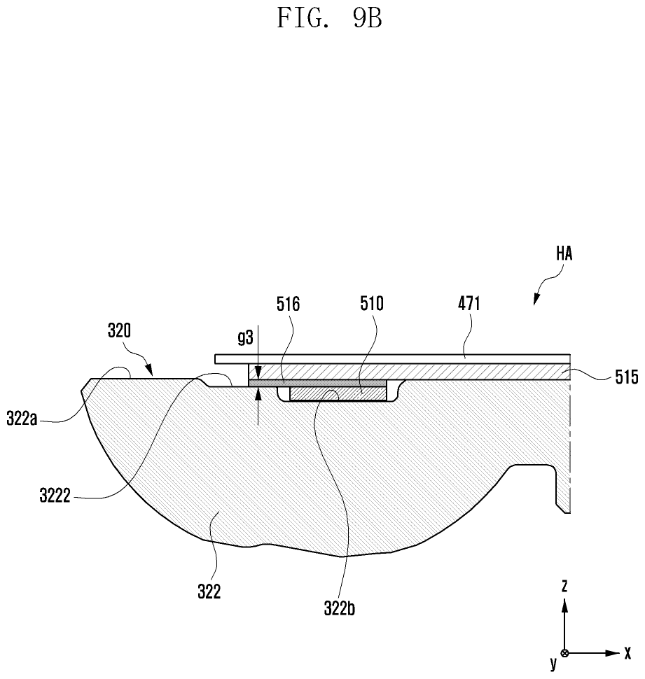

FIG. 9A is a diagram illustrating a partial configuration of a hinge assembly according to various embodiments. FIG. 9B is a partial cross-sectional view of the hinge assembly taken along line 9b-9b of FIG. 9A according to various embodiments.

In describing the hinge assembly HA of FIGS. 9A and 9B, components that are substantially the same as those of the hinge assembly HA of FIGS. 8A and 8B are given the same reference symbols, and detailed descriptions thereof may be omitted.

With reference to FIGS. 9A and 9B, in the configuration of FIG. 8B, the hinge assembly HA may include a second buffer member 516 (e.g., second cushion) arranged to fill the gap (g3) between the first buffer member 515 and the first recess 3222. In an embodiment, the second buffer member 516 may be extended to be positioned between the first hinge plate 510 and the first buffer member 515. In this case, the depth of the first receiving groove 322b may be increased by the thickness of the second buffer member 516. In an embodiment, while the thickness of the first receiving groove 322b is maintained, the first hinge plate 510 may be formed to be as thin as the thickness of the second buffer member 516 (e.g., thinning process). For example, through additional arrangement of the second buffer member 516 (e.g., stacked structure of the first buffer member 515 and the second buffer member 516), when an external impact occurs, the stress concentrated on the step at the boundary between the first lower layer 471 and the rear surface of the flexible display 230 can be dispersed, thereby helping to improve the overall screen durability of the flexible display 230. In one embodiment, the hinge assembly (HA) may include a buffer member (526) disposed on the second rotation member (323) in substantially the same manner as the second buffer member (516) disposed on the first rotation member (322).

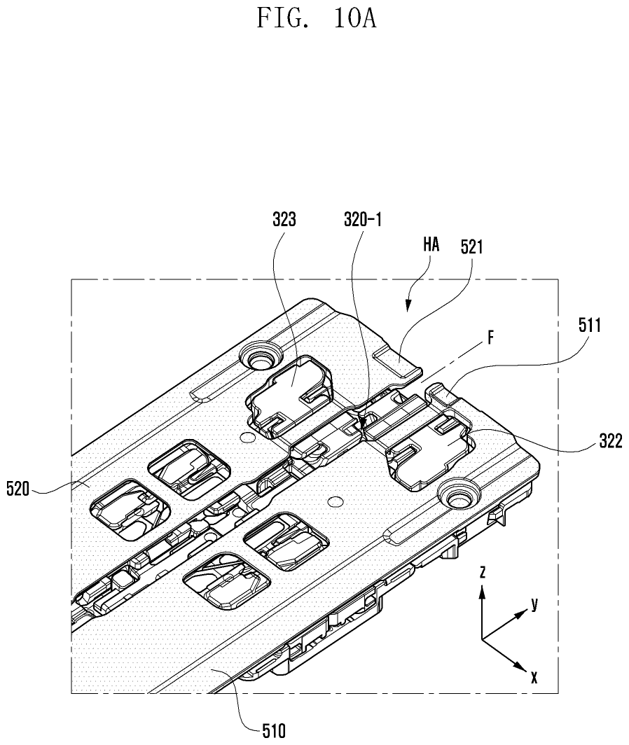

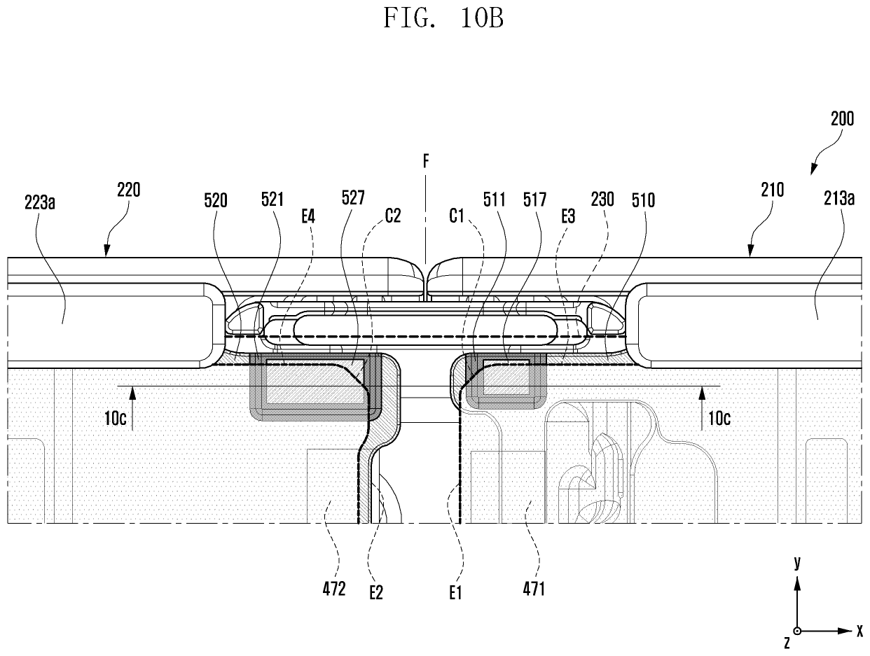

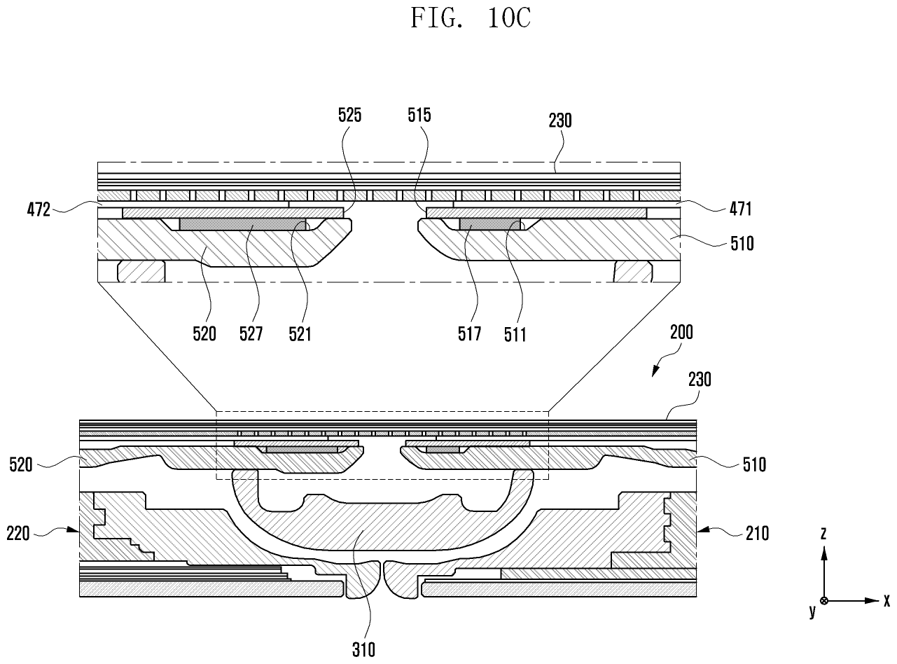

FIG. 10A is a partial perspective view of a hinge assembly according to various embodiments. FIG. 10B is a diagram illustrating a partial configuration of the electronic device according to various embodiments. FIG. 10C is a partial cross-sectional view of the electronic device taken along line 10c-10c of FIG. 10B according to various embodiments.

With reference to FIGS. 10A, 10B and 10C (which may be referred to as FIGS. 10A to 10C), the hinge assembly HA may include a hinge module 320-1, a first hinge plate 510 disposed at least partially between the hinge module 320-1 and the first lower layer 471, and a second hinge plate 520 disposed at least partially between the hinge module 320 and the second lower layer 472, which are on top of the hinge module 320-1. In an embodiment, the first lower layer 471 may include a first corner C1 formed through the third edge E3 extended from one end of the first edge E1 in a direction perpendicular to the folding axis (F) (e.g., x-axis direction). In an embodiment, the second lower layer 472 may include a second corner C2 formed through the fourth edge E4 extended from one end of the second edge E2 in a direction perpendicular to the folding axis (F) (e.g., negative x-axis direction).

According to various embodiments, a third buffer member 517 (e.g., cushion member or tape member) may be included between the first hinge plate 510 and the first lower layer 471 at a position overlapping at least a portion of the first corner C1 and/or the third edge E3 when the flexible display 230 is viewed from above. In an embodiment, a fourth buffer member 527 may be included between the second hinge plate 520 and the second lower layer 472 at a position overlapping at least a portion of the second corner C2 and/or the fourth edge E4 when the flexible display 230 is viewed from above. For example, in the folding region (e.g., folding region 230c in FIG. 2A) of the flexible display 230, the upper end (e.g., upper edge) may be vulnerable to external impact, so the impact applied to the flexible display 230 may be effectively dispersed through the third buffer member 517 and the fourth buffer member 527.

According to various embodiments, the third buffer member 517 may be disposed in a manner of being seated in the first seating groove 511 formed to be lower than the outer surface of the first hinge plate 510. In an embodiment, the first seating groove 511 may be formed to have a depth such that the third buffer member 517 is aligned with or at least not higher than the outer surface of the first hinge plate 510. In an embodiment, the fourth buffer member 527 may be disposed in a manner of being seated in the second seating groove 521 formed to be lower than the outer surface of the second hinge plate 520. In an embodiment, the second seating groove 521 may be formed to have a depth such that the fourth buffer member 527 is aligned with or at least not higher than the outer surface of the second hinge plate 520. Although not shown, in the folding region (e.g., folding region 230c in FIG. 2A) of the flexible display 230, buffer members (e.g., third buffer member 517 and fourth buffer member 527) may also be applied to the lower end (e.g., lower edge) in substantially the same manner.

According to various example embodiments, the electronic device may include: a first housing (e.g., first housing 210 in FIG. 7A); a second housing (e.g., second housing 220 in FIG. 7A); a flexible display (e.g., flexible display 230 in FIG. 7A) disposed to be supported by the first housing and the second housing and configured to be bendable with respect to a folding axis (e.g., folding axis (F) in FIG. 6A); a first lower layer (e.g., first lower layer 471 in FIG. 7A) disposed at a position corresponding to at least a portion of the first housing under the flexible display; a second lower layer (e.g., second lower layer 472 in FIG. 7A) disposed at a position corresponding to at least a portion of the second housing under the flexible display, and arranged to have a first gap (e.g., first gap (g1) in FIG. 7A) with the first lower layer in a direction parallel to the folding axis; and at least one hinge module (e.g., hinge module 320 in FIG. 7A) including a hinge rotatably connecting the first housing and the second housing with respect to each other. The hinge module may include: a support body (e.g., support body 321 in FIG. 7A); a first rotation member (e.g., first rotation member 322 in FIG. 7A) comprising a rotation body rotatably coupled to the support body at one end, connected to the first housing at the other end, and at least partially supporting the first lower layer; and a second rotation member (e.g., second rotation member 323 in FIG. 5A) comprising a rotation body rotatably coupled to the support body at one end, connected to the second housing at the other end, and at least partially supporting the second lower layer, wherein the first rotation member may include a first recess (e.g., first recess 3221 in FIG. 7A) lower than a first upper surface (e.g., first upper surface 322a in FIG. 7A) of the first rotation member in a region overlapping at least a first edge of the first lower layer when the flexible display is viewed from above, and wherein the second rotation member may include a second recess (e.g., second recess 3231 in FIG. 5A) lower than a second upper surface of the second rotation member (e.g., second rotation member 323 in FIG. 5A) in a region overlapping at least a second edge of the second lower layer when the flexible display is viewed from above.

According to various example embodiments, a portion of the first recess and/or a portion of the second recess may be disposed at a position overlapping with the first gap when the flexible display is viewed from above.

According to various example embodiments, a remaining portion of the first recess and/or a remaining portion of the second recess may be disposed at a position not overlapping with the first gap when the flexible display is viewed from above.

According to various example embodiments, the first recess may have a depth equal to or greater than a step difference between the rear surface of the flexible display and the first lower layer.

According to various example embodiments, the second recess may have a depth equal to or greater than a step difference between the rear surface of the flexible display and the second lower layer.

According to various example embodiments, the first recess may have a depth configured to allow, based on the flexible display being deformed, the rear surface of the flexible display to make line contact with the upper surface of the first rotation member before the first edge of the first lower layer comes into contact with the surface of the first recess.

According to various example embodiments, the second recess may have a depth configured to allow, based on the flexible display being deformed, the rear surface of the flexible display to make line contact with the first upper surface of the first rotation member before the second edge of the second lower layer comes into contact with the surface of the second recess.

According to various example embodiments, the electronic device may include: a first hinge plate (e.g., first hinge plate 510 in FIG. 7A) disposed between the first lower layer and the first rotation member, and a second hinge plate (e.g., second hinge plate 520 in FIG. 7A) disposed between the second lower layer and the second rotation member, wherein the first hinge plate and the second hinge plate may be disposed to have a second gap (e.g., second gap (g2) in FIG. 7A) in a direction parallel to the folding axis.

According to various example embodiments, in a first section (e.g., first section S1 in FIG. 7A) corresponding to the first recess along the folding axis and/or a second section (e.g., second section S2 in FIG. 7A) corresponding to the second recess, the first gap may be at least equal to or smaller than the second gap.

According to various example embodiments, the first rotation member may be disposed such that at least a portion of the first upper surface including the first recess faces the rear surface of the flexible display through the second gap.

According to various example embodiments, the first rotation member may be disposed such that a surface of the first hinge plate coincides with at least a portion of the surface of the first rotation member exposed through the second gap.

According to various example embodiments, the electronic device may include a first buffer member (e.g., first buffer member 515 in FIG. 7A) comprising a flexible material disposed between the first hinge plate and the first lower layer.

According to various example embodiments, a portion of the first buffer member may be disposed between the first rotation member and the first lower layer in a region where the first rotation member is exposed through the second gap.

According to various example embodiments, the electronic device may include a second buffer member (e.g., second buffer member 516 in FIG. 7A) comprising a flexible material disposed between the first buffer member and the first hinge plate at a position corresponding to at least a portion of the first rotation member.

According to various example embodiments, the first lower layer may include a first corner (e.g., first corner C1 in FIG. 10B) formed through a third edge (e.g., third edge E3 in FIG. 10B) extending from one end of the first edge in a direction perpendicular to the folding axis, and the electronic device may include a third buffer member (e.g., third buffer member 517 in FIG. 10B) comprising a flexible material disposed between the first hinge plate and the first lower layer at a position overlapping with at least a portion of the first corner and/or the third edge when the flexible display is viewed from above.

According to various example embodiments, the third buffer member may be seated in a first seating groove (e.g., first seating groove 511 in FIG. 10B) lower than the outer surface of the first hinge plate so as to coincide with the outer surface of the first hinge plate.

According to various example embodiments, the second lower layer may include a second corner (e.g., second corner C2 in FIG. 10B) formed through a fourth edge (e.g., fourth edge E4 in FIG. 10B) extending from one end of the second edge in a direction perpendicular to the folding axis, and may include a fourth buffer member (e.g., fourth buffer member 527 in FIG. 10B) comprising a flexible material disposed between the second hinge plate and the second lower layer at a position overlapping at least a portion of the second corner and/or the fourth edge when the flexible display is viewed from above.

According to various example embodiments, the fourth buffer member may be seated in a second seating groove (e.g., second seating groove 521 in FIG. 10B) lower than the outer surface of the second hinge plate so as to coincide with the outer surface of the second hinge plate.

According to various example embodiments, the first lower layer and/or the second lower layer may include a digitizer and/or a reinforcing plate (e.g., first reinforcing plate 461 and second reinforcing plate 462 in FIG. 4).

According to various example embodiments, the flexible display may include a window layer (e.g., window layer 410 in FIG. 4), a display panel (e.g., display panel 430 in FIG. 4) disposed under the window layer, and a support plate (e.g., support plate 450 in FIG. 4) disposed under the display panel and configured to provide foldable flexibility to the flexible display with respect to the folding axis.

While the disclosure has been illustrated and described with reference to various example embodiments, it will be understood that the various example embodiments are intended to be illustrative, not limiting. It will be understood by those skilled in the art that the scope of the disclosure includes all changes or modifications derived based on the technical ideas of the various embodiments of the disclosure in addition to those embodiments disclosed herein, including the appended claims and their equivalents. It will also be understood that any of the embodiment(s) described herein may be used in conjunction with any other embodiment(s) described herein.

What is claimed is:

1. An electronic device comprising:
a first housing;
a second housing;
a flexible display disposed to be supported by the first housing and the second housing and configured to be bendable with respect to a folding axis;
a first lower layer disposed at a position corresponding to at least a portion of the first housing under the flexible display;
a second lower layer disposed at a position corresponding to at least a portion of the second housing under the flexible display, and arranged to have a first gap with the first lower layer in a direction parallel to the folding axis; and
at least one hinge module configured to rotatably connect the first housing and the second housing with respect to each other,
wherein the hinge module includes:
a support body;
a first rotation member rotatably coupled to the support body at one end, connected to the first housing at the other end, and at least partially supporting the first lower layer; and
a second rotation member rotatably coupled to the support body at one end, connected to the second housing at the other end, and at least partially supporting the second lower layer,
wherein the first rotation member includes a first recess lower than a first upper surface of the first rotation member in a region overlapping at least a first edge of the first lower layer when the flexible display is viewed from above,
wherein the second rotation member includes a second recess lower than a second upper surface of the second rotation member in a region overlapping at least a second edge of the second lower layer when the flexible display is viewed from above.

2. The electronic device of claim 1, wherein a portion of the first recess and/or a portion of the second recess are disposed at a position overlapping with the first gap when the flexible display is viewed from above.

3. The electronic device of claim 2, wherein a remaining portion of the first recess and/or a remaining portion of the second recess are disposed at a position not overlapping with the first gap when the flexible display is viewed from above.

4. The electronic device of claim 1, wherein the first recess has a depth equal to or greater than a step difference between a rear surface of the flexible display and the first lower layer.

5. The electronic device of claim 1, wherein the second recess has a depth equal to or greater than a step difference between the rear surface of the flexible display and the second lower layer.

6. The electronic device of claim 1, wherein the first recess has a depth configured to allow, based on the flexible display being deformed, the rear surface of the flexible display to make line contact with a first upper surface of the first rotation member before the first edge of the first lower layer comes into contact with a surface of the first recess.

7. The electronic device of claim 1, wherein the second recess has a depth configured to allow, based on the flexible display being deformed, the rear surface of the flexible display to make line contact with the upper surface of the first rotation member before the second edge of the second lower layer comes into contact with a surface of the second recess.

8. The electronic device of claim 1, comprising:
a first hinge plate disposed between the first lower layer and the first rotation member; and
a second hinge plate disposed between the second lower layer and the second rotation member,
wherein the first hinge plate and the second hinge plate are disposed to have a second gap in a direction parallel to the folding axis.

9. The electronic device of claim 8, wherein the first gap is at least equal to or smaller than the second gap in a first section corresponding to the first recess along the folding axis and/or a second section corresponding to the second recess.

10. The electronic device of claim 8, wherein the first rotation member is disposed so that at least a portion of the first upper surface including the first recess faces the rear surface of the flexible display through the second gap.

11. The electronic device of claim 10, wherein the first rotation member is disposed so that a surface of the first hinge plate coincides with at least a portion of the surface of the first rotation member exposed through the second gap.

12. The electronic device of claim 10, comprising a first buffer member disposed between the first hinge plate and the first lower layer.

13. The electronic device of claim 12, wherein a portion of the first buffer member is disposed between the first rotation member and the first lower layer in a region where the first rotation member is exposed through the second gap.

14. The electronic device of claim 10, comprising a second buffer member disposed between the first buffer member and the first hinge plate at a position corresponding to at least a portion of the first rotation member.

15. The electronic device of claim 7, wherein:
the first lower layer includes a first corner formed through a third edge extending from one end of the first edge in a direction perpendicular to the folding axis; and
the electronic device comprises a third buffer member disposed between the first hinge plate and the first lower layer at a position overlapping with at least a portion of the first corner and/or the third edge when the flexible display is viewed from above.

16. The electronic device of claim 15, wherein the third buffer member is seated in a first seating groove lower than the outer surface of the first hinge plate so as to coincide with the outer surface of the first hinge plate.

17. The electronic device of claim 16, wherein the second lower layer includes a second corner formed through a fourth edge extending from one end of the second edge in a direction perpendicular to the folding axis, and
wherein further comprising a fourth buffer member comprising a flexible material disposed between the second hinge plate and the second lower layer at a position overlapping at least a portion of at least one of the second corner and the fourth edge when the flexible display is viewed from above.

18. The electronic device of claim 17, wherein the fourth buffer member is seated in a second seating groove lower than the outer surface of the second hinge plate so as to coincide with the outer surface of the second hinge plate.

19. The electronic device of claim 1, wherein at least one of the first lower layer and the second lower layer includes at least one of digitizer and a reinforcing plate.

20. The electronic device of claim 1, wherein the flexible display includes a window layer, a display panel disposed under the window layer, and a support plate disposed under the display panel, the support plate being configured to provide foldable flexibility to the flexible display with respect to the folding axis.
